(19) United States
(12) Patent Application Publication
(10) Pub. No.: US 2024/0250024 A1
(43) Pub. Date: Jul. 25, 2024

(54) CHOPLESS FLOW FOR STAIRLESS ELECTRICAL INTERCONNECT STRUCTURE

(71) Applicant: Micron Technology, Inc., Boise, ID (US)

(72) Inventors: Surendranath C. Eruvuru, Boise, ID (US); Lifang Xu, Boise, ID (US)

(21) Appl. No.: 18/420,074

(22) Filed: Jan. 23, 2024

Related U.S. Application Data
(60) Provisional application No. 63/441,034, filed on Jan. 25, 2023.

(51) Int. Cl. H01L 23/528; G11C 16/04; H10B 41/10; H10B 41/20; H10B 41/35; H10B 43/10; H10B 43/20; H10B 43/35

(52) U.S. Cl. CPC H01L 23/5283; G11C 16/0483; H10B 41/10; H10B 41/20; H10B 41/35; H10B 43/10; H10B 43/20; H10B 43/35

(57) ABSTRACT

A stairless electrical interconnect structure with contact pillars embedded within and collectively accessing each tier in a periodic material stack, e.g., to provide electrical connections to access lines associated with a three-dimensional memory array, is described. The contact pillars can be formed in a corresponding array of vertical contact pillar trenches etched into the material stack in two stages to create depths of the trenches that vary between columns by a fixed number of tiers and then offset the depths between rows.

### PRIORITY APPLICATION

This application claims the benefit of priority to U.S. Provisional Application Ser. No. 63/441,034, filed Jan. 25, 2023, which is incorporated herein by reference in its entirety.

### BACKGROUND

Over decades, the bit densities of computer memory devices, such as dynamic random-access memory (DRAM) or NAND or NOR flash memory, underwent a largely exponential growth, contributing to the ever-increasing memory capacity of electronic devices.

With memory scaling in two dimensions approaching the end of the roadmap, more recent technology developments have extended memory structures into the third dimension. With a three-dimensional (3D) array of memory cells, however, comes the challenge of providing electrical interconnect structures to access the individual device tiers within the 3D array.

### BRIEF DESCRIPTION OF THE DRAWINGS

The accompanying drawings illustrate an example stairless electrical interconnect structure and associated process flow. In the drawings, various fill patterns and hatch styles are used to provide a visual contrast between different material layers and device components. These fill patterns and hatch styles are not intended to limit the choice of material for the respective layer or device component (and may deviate from conventions regarding the depiction of various materials); instead, suitable materials are listed in the textual description.

FIG. 1 shows, in cross-sectional view, an initial material stack including a periodic material sub-stack in which 3D memory arrays and associated electrical interconnect structures may be formed.

FIG. 2 shows the material stack of FIG. 1, in cross-sectional view, after a hard mask layer of the stack has been patterned to form vertical openings.

FIG. 3 shows the material stack of FIG. 2 in top view, illustrating the arrangement of the vertical openings in a two-dimensional horizontal array, alongside a memory array.

FIGS. 4 and 5 show the material stack, in top and cross-sectional views, respectively, with a thick photoresist layer deposited over the patterned hard mask layer of FIG. 2, patterned to expose a region encompassing a central pair of columns of openings through the hard mask layer.

FIG. 6 shows, in cross-sectional view, the structure in the material stack of FIG. 1 that results from completion of the first etch cycle in a first stage of etch cycles.

FIG. 7 shows, in top view, the photoresist layer of FIG. 4 trimmed, for the second etch cycle in the first stage, to expose a larger region encompassing an additional pair of columns of openings through the hard mask layer.

FIG. 8 shows, in cross-sectional view, the structure in the material stack of FIG. 1 that results from completion of the second etch cycle.

FIG. 9 shows, in cross-sectional view, a stadium structure of contact pillar trenches in the created in the material stack of FIG. 1 after removal of the remaining photoresist layer.

FIGS. 10 and 11 show, in top and cross-sectional views, respectively, a new photoresist layer deposited over the material stack of FIG. 1, patterned to expose a region encompassing one half-stadium of contact pillar trenches of the stadium structure of FIG. 9.

FIGS. 12 shows, in cross-sectional view, the structure in the material stack that results from completion of a single additional first-stage etch cycle extending the exposed contact pillar trenches and openings of FIG. 11 three tiers down into the periodic material stack.

FIG. 13 shows the material stack, in top view, with a new photoresist layer patterned to expose a horizontal region encompassing two rows of the contact pillar trenches of FIG. 12.

FIG. 14 shows the material stack, in cross-sectional view, for a row of contact pillar trenches that is covered by the new photoresist layer of FIG. 13 following the initial patterning.

FIG. 15 shows the material stack, in cross-sectional view, for a row of contact pillar trenches in the exposed region of FIG. 13 following the first etch cycle of the second stage.

FIG. 16 shows the material stack, in top view, after the new photoresist layer of FIG. 13 has been trimmed to expose a larger region encompassing an additional pair of rows of contact pillar trenches.

FIG. 17 shows, in cross-sectional view, a row of contact pillar trenches that is still covered by the photoresist layer of FIG. 16.

FIG. 18 shows, in cross-sectional view, a newly exposed row of contact pillar trenches in the exposed region following the second etch cycle of the second stage.

FIG. 19 shows, in cross-sectional view, the previously exposed row of contact pillar trenches in the exposed region of FIGS. 13 and 16 following the second etch cycle of the second stage.

FIG. 20 shows, in cross-sectional view, the row of contact pillar trenches of FIG. 17 in the material stack after recesses extending from the contact pillar trenches have been etched into material layers that are subsequently to be replaced with an electrically conductor material.

FIG. 21 shows, in cross-sectional view, the row of contact pillar trenches of FIG. 20 after the walls of the contact pillar trenches have been lined and the recesses been filled with an electrically insulating material.

FIG. 22 shows, in cross-sectional view, the row of contact pillar trenches of FIG. 21 after the lined trenches have been filled with sacrificial fill.

FIG. 23 shows, in cross-sectional view, the material stack with the row of contact pillar trenches of FIG. 22 after complete removal of the hard mask layer.

FIG. 24 shows, in cross-sectional view, a new material stack resulting from replacement of the non-conductive layers in the material stack of FIG. 23 with a conductive material.

FIG. 25 shows, in cross-sectional view, the new material stack of FIG. 24 with a photoresist layer deposited over a dielectric layer of the stack, patterned to form openings above the filled contact pillar trenches.

FIG. 26 shows, in cross-sectional view, the openings in the photoresist layer of FIG. 25 extended down to the filled contact pillar trenches.

FIG. 27 shows, in cross-sectional view, the contact pillar trenches in the material stack of FIG. 24 reopened and extended through the insulating liner into the electrically conductive layer of the immediately adjacent tier.

FIG. 28 shows, in cross-sectional view, the re-opened contact pillar trenches of FIG. 27 filled with an electrically conductive material to form contact pillars.

FIGS. 29 and 30 show, in cross-sectional and top views, respectively, the final electric interconnect structure formed by the contact pillars of FIG. 28 alongside the adjacent memory arrays.

### DETAILED DESCRIPTION

Described herein are electrical interconnect structures for accessing each of a plurality of tiers within a periodic material stack, along with process flows for creating such structures. The disclosed electrical interconnect structures are generally suitable for accessing tiers of memory cells within monolithic multi-layer implementations of 3D memory arrays (e.g., 3D DRAM, or 3D NAND or NOR flash memory), e.g., wherein the memory cells are formed along an array of vertically extending pillars, with horizontal access lines (word lines) extending within each tier. The terms “horizontal/lateral” and “vertical/longitudinal” are herein used with reference to the material stack in which the memory and electrical interconnect structure are formed, and irrespective of the orientation of the stack relative to the earth's gravitational field. “Horizontal/lateral” means within or parallel to the plane of the material layers and the major plane of any underlying substrate on which they are formed, and “vertical/longitudinal” means normal/perpendicular to the plane of the material layers and major plane of the substrate, in the direction in which the layers are stacked.

Conventionally, electrical connections to the access lines within a 3D array of memory cells are sometimes established via a staircase structure that exposes individual tiers sequentially along a lateral dimension, forming a series of “steps” to which electrically conductive contact pillars can connect. In contrast, the electrical interconnect structure described herein is free of stair-step structures (is “stairless” in this sense), and is instead formed with an array of vertical contact pillars embedded within the material stack, arranged in “rows” and “columns” along the horizontal plane. Each row of contact pillars corresponds to a group of pillars spread out along a first horizontal direction, and each column of contact pillars corresponds to a group of pillars spread out along a second horizontal direction different from, and typically (although not necessarily) orthogonal to, the first horizontal direction. The contact pillars extend to different depths within the stack so as to collectively reach the various tiers of the 3D memory array. In some embodiments, the contact pillars within each column vary in depth between rows so as to collectively contact a specified number n of consecutive tiers of the plurality of consecutive tiers, and the contact pillars within each row vary in depth between columns so as to collectively contact every n-th tier of the plurality of consecutive tiers.

The array of vertical contact pillars may be formed by etching a corresponding array of vertical contact pillar trenches extending to different depths within the material stack, and then filling the trenches with electrically conductive material. In various embodiments, the locations of the vertical contact pillar trenches are defined with an initial array of openings extending through a hard mask disposed on top of the material stack, and the openings are then vertically extended into the material stack, to form contact pillar trenches extending to the various depths, in two multi-cycle stages.

In the first stage, multiple columns of contact pillar trenches that vary in depth by a specified small number d of tiers (for instance, between two and ten tiers, e.g., six tiers) between neighboring columns are created in a series of first-stage etch cycles applied to increasingly larger exposed areas that encompass an increasing number of columns of the initial array of openings (the remaining, unexposed area being masked off). In each first-stage etch cycle, a new column of trenches is extended into the material stack by etching through the first d tiers in the corresponding newly exposed area while the trenches created in previous cycles are each extended in depth by d tiers. With one column added in each cycle in a given direction (along the rows), a series of m columns linearly decreasing in depth (in steps of d tiers) in that direction from (m−1)×d tiers to 0 tiers can be created in (m−1) such etch cycles, the m-th column corresponding to openings that have not yet been extended into the tiers of the stack. In some embodiments, the columns of m trenches are created and extended in pairs arranged symmetrically about a pair of center columns created first, in (m/2−1) etch cycles, resulting in columns of contact pillar trenches whose depth decreases linearly in both directions away from the center pair. In this case, one half of the contact pillar trenches, corresponding to the columns to one side of a center line between the pair of center columns, may undergo an additional etch cycle that etches through an additional d/2 tiers, overall offsetting the depths of the contact pillar trenches by d/2 tiers between the columns to both sides of the center line. At the end of the first stage, the contact pillar trenches within each row extend to every n-th tier within the stack, where n=d without and n=d/2 with the additional offsetting etch cycle.

In the second stage, the array of contact pillar trenches created in the first stage (including the m-th column that is still at depth 0) are further selectively extended, in groups corresponding to rows of the array, to create varying depths along each column, in a series of second-stage etch cycles applied to increasingly larger exposed areas that encompass an increasing number of rows of the array (the remaining, unexposed area being masked off). In each second-stage etch cycle, each exposed contact pillar trench is extended by one tier, and the number of etch cycles is selected based on n such that the final array includes a pillar trench extending to each of m×n consecutive tiers. If a single set of columns of trenches differing in depth by d is created in the first stage, the number of second-stage etch cycles is n=d. If the first stage results in the creation of two sets of columns with etch depths differing within each set by d and offset between sets by d/2, the number of second-stage etch cycles is n=d/2.

As those of ordinary skill in the art will understand, the same array of contact pillar trenches can also be created by using the above processing stages and steps in different order, e.g., first etching the rows one tier at a time, and then etching the columns d tiers at a time.

The described process flow for creating a stairless electrical interconnect structure provides various cost and process benefits. Compared with conventional staircase designs, where following the staircase formation, an oxide fill is applied and etched to form contact pillar trenches, the contact pillar trenches in the stairless design are created directly in the material stack in which the 3D array is formed, eliminating the need for high aspect-ratio staircase patterning and fill, and the associated fail modes (e.g., cracks, broken bridge, etc.), and the word line contact etch and associated punch-through/underetch. Moreover, the stairless design provides further staircase scaling paths and is naturally bidirectional and suited for half-wordline architectures. Further, compared with processes for stairless electrical interconnect structures that, after creating multiple shallow staircases in the top layers of the material stack, use chop etches to selectively transfer these staircases deeper down into the stack (e.g., by ten or tens of tiers) to ultimately access each tier within the stack, the disclosed process flow creates the stairless interconnect structure using a sequence of one-tier punch etches, i.e., it is “chop-less.” A punch etch utilizes a signal from the etch stop layer for each cycle as feedback to end the etch precisely at the desired layer, avoiding or at least significantly reducing the risk of underetch or overetch that is associated with a chop etch, where the etch cycle duration is precalculated.

In an interconnect structure having a single row of contact pillars increasing in depth linearly by one tier between adjacent pillars to access each tier within the stack, the improved control over the depth of each contact pillar trench that is achieved by a chop-less process generally comes at the cost of more manufacturing steps involving patterning and etching of each individual layer, rendering it impractical to reach a large number of tiers. The disclosed process for creating a two-dimensional array of contact pillars mitigates this problem by etching several layers deep between patterning steps to create the columns of contact pillar trenches in the first stage, and then extending entire rows of contact pillar trenches in the second stage. For example, an array of N=m×n contact pillars in m columns and n rows, with depths increasing linearly by n tiers along each row and offsets of one tier between adjacent rows, may be created using (m−1) patterning and etch cycles in the first stage and (n−1) patterning and etch cycles in the second stage for a total of m+n−2 patterning and etch cycles, whereas the same number of contact pillars arranged along a single row would take (N−1)=(m×n)−1 patterning and etch cycles to create. An additional benefit of the two-dimensional array of contact pillars is the compactness and smaller footprint associated with this arrangement.

The foregoing summary will be more readily understood from the following detailed description of the accompanying drawings.

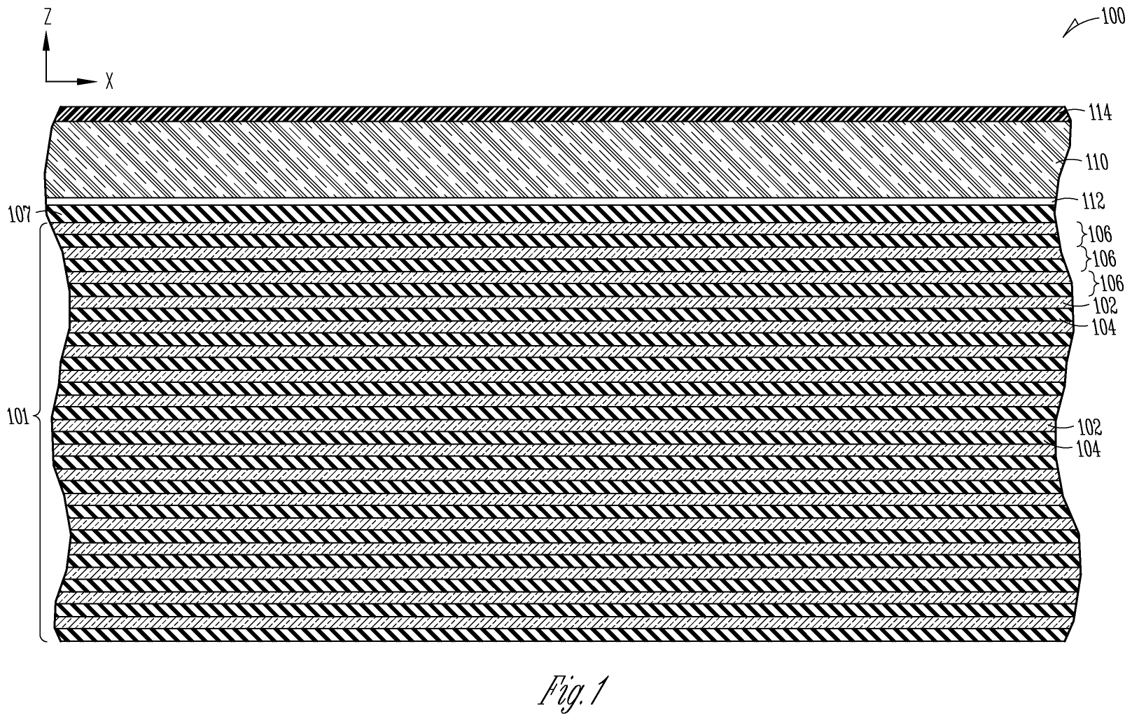

FIGS. 1-28 illustrate an example process flow for creating a stairless electrical interconnect structure with cross-sectional and top views of a number of structures sequentially formed during the process. The cross-sectional views are all taken in the x-z plane, where x is a horizontal direction, and z is the vertical direction in which the materials are stacked. The top views all show the x-y plane. In various embodiments, the x direction corresponds to the general direction of the access lines used to access a 3D memory array adjacent to the electrical interconnect structure.

FIG. 1 shows, in cross-sectional view, an initial material stack 100, including a periodic material sub-stack 101 (herein also referenced as the “periodic material stack” or “periodic stack”) in which 3D memory arrays and associated electrical interconnect structures may be formed. The material stack 100 may be formed on an underlying bulk substrate (e.g., a silicon, silicon-on-insulator, germanium, silicon-on-glass, or other semiconductor substrate), in some cases with intervening layers formed on the substrate underneath the periodic stack 101 (neither the substrate nor any intervening layers being shown). The layers of the material stack may be formed on the substrate using one or more layer deposition techniques known in the art, such as, without limitation, chemical vapor deposition, physical vapor deposition, atomic layer deposition, or spin-coating.

As shown, the periodic material stack 101 may include alternating layers of a first material (layers 102) and a second material (layers 104). More generally, the periodic stack 101 includes a vertically periodic arrangement of two or more materials. The set of layers within each period (e.g., as shown, each pair of adjacent layers 102, 104) forms a tier 106 of the periodic stack 101. Each tier 106 generally corresponds to one device level within an associated 3D memory array and includes the layers in which the memory cells are formed and, if applicable, any separation level between adjacent device levels. The periodic stack 101 may include many more tiers 106 than shown (e.g., hundreds of tiers).

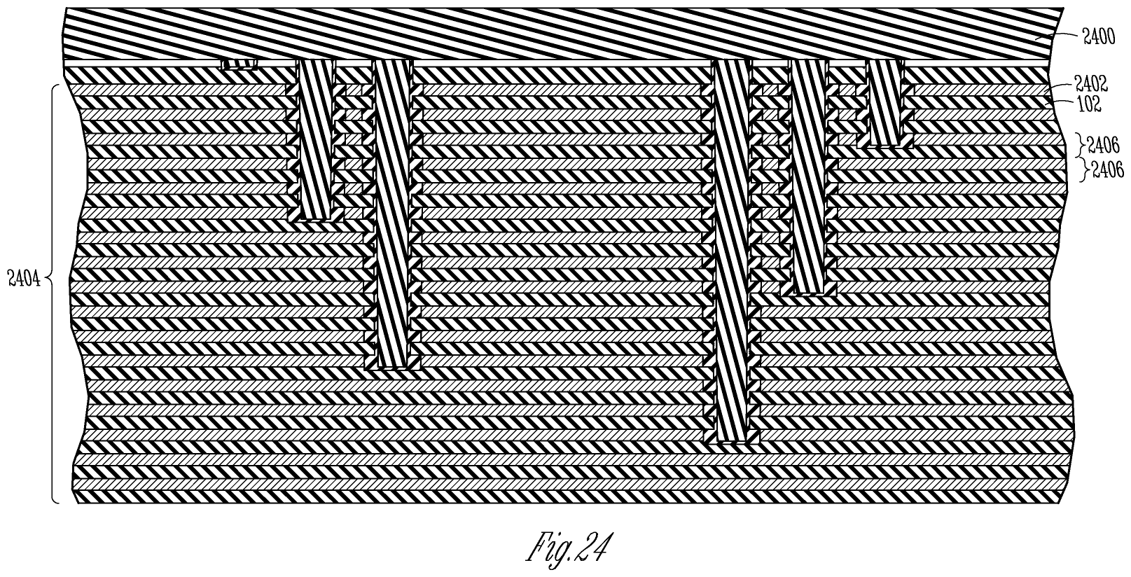

The layers in the periodic material stack 101 generally exhibit a high degree of uniformity. Further, corresponding layers of the same material may be equal in thickness across all tiers 106, while the thickness of the layers of one material may differ from the thickness of the layers of another material. (Note that, as shown, the periodic stack 101 may be topped off with an additional layer 107 of one of the materials, which is not part of a tier 106 within the periodic stack 101 and as such need not have the same thickness as the other layers of that material within the stack 100.) The materials of the layers of the periodic material stack 101 are chosen to exhibit significantly different etch rates for a suitable etchant, allowing one of the layers, which is for this reason also referred to as the “sacrificial layer,” to be ultimately selectively etched away and the resulting space be backfilled with an electrically conductive material (e.g., tungsten or some other metal) to form the access line (word line) connections to the memory array (in later processing steps, as shown in FIG. 24). For example, layers 102 and 104 may be made of silicon oxide and silicon nitride, respectively. In the example described herein, silicon nitride layer 104 is the sacrificial layer.

In preparation for subsequent processing, the periodic material stack 101 is covered by a hard mask layer 110 (e.g., of polysilicon) deposited on top of an intervening thin etch stop layer 112 (e.g., of carbon nitride, hafnium oxide (Hf₂ ), buried oxide (Box), zirconium (ZrOₓ)). Optionally, a thin sacrificial oxide layer 114 may be deposited on top of the hard mask layer 110 to facilitate adhesion of a subsequently deposited photoresist layer (not shown) for patterning the hard mask layer 110.

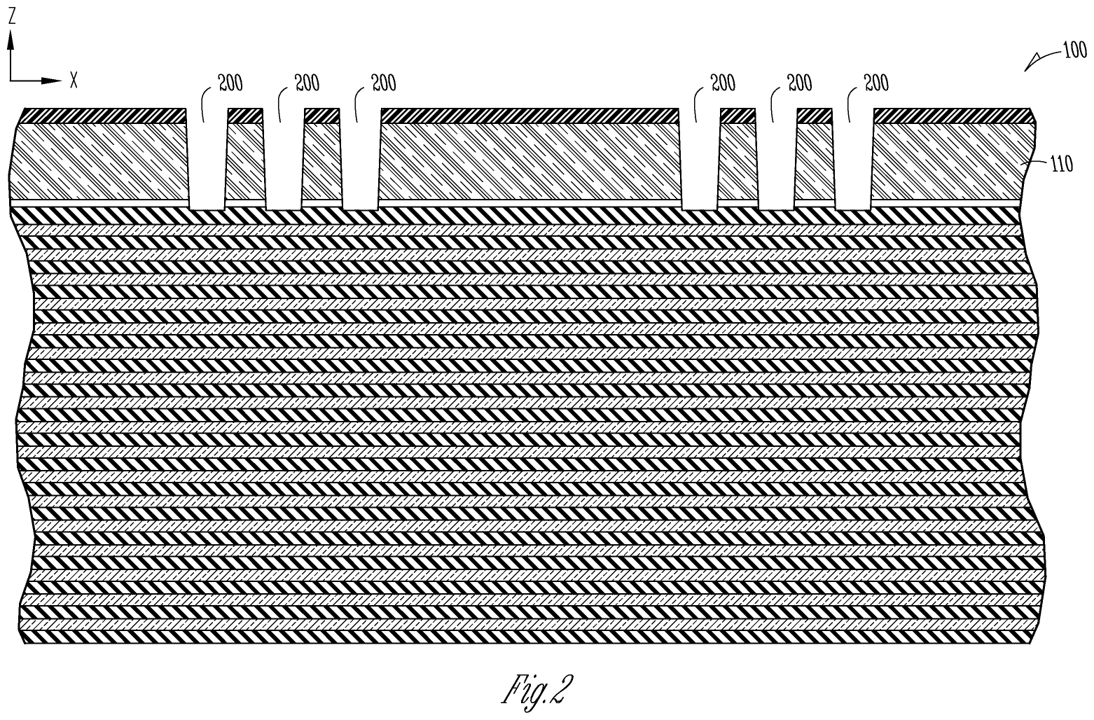

FIG. 2 shows the material stack 100, in cross-sectional view, after the hard mask layer 110 has been patterned to form vertical openings 200 extending through the optional sacrificial oxide layer 114, the hard mask layer 110, and the etch stop layer 112, and ending in the top-most layer 107 of silicon oxide, right above the top-most tier 106 of the periodic stack. To create the openings 200, a photoresist layer (not shown) may be deposited on top of the hard mask layer 110 or sacrificial oxide layer 114 and then photolithographically patterned. Photolithographic patterning, as is well-known in the art, involves the selective exposure of the photoresist layer to light (e.g., in the ultraviolet regime) using a photomask or imaging device, followed by a development process in which the photoresist is removed with a suitable solvent from the exposed (in case of a positive photoresist) or unexposed (in case of a negative photoresist) portions of the photoresist layer. The pattern thus created in the photoresist layer can then be transferred into the underlying material layers, in this case the hard mask layer 110 and adjacent layers 112, 114. For instance, material in these underlying layers can be removed selectively in the exposed regions (that is, the regions not masked by the patterned photoresist layer) by a directional (anisotropic) etching process, such as a dry etching (e.g., reactive ion etching). Alternative methods for patterning the hard mask layer 110 may occur to those of ordinary skill in the art.

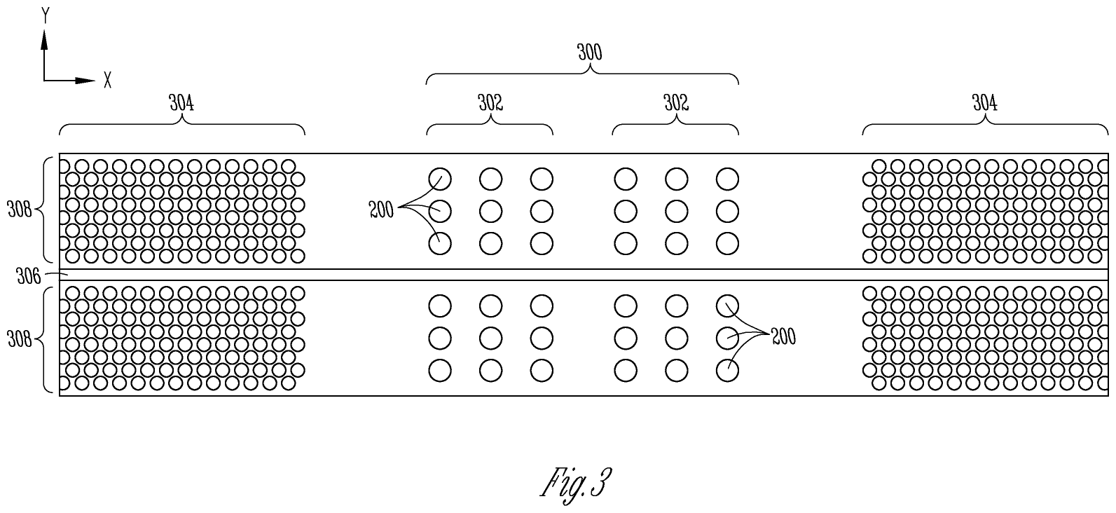

FIG. 3 shows the material stack 100 with the patterned hard mask layer 112 in top view (corresponding to the x-y plane), illustrating the arrangement of the vertical openings 200 in a two-dimensional horizontal array of rows (in the x direction) and columns (in the y direction) that extends over a region 300 where the array of contact pillars forming the electrical interconnect structure is being created (hereinafter the “electrical interconnect region” 300). The array may include multiple sub-arrays, and openings 200 within each sub-array may be uniformly spaced. As can be seen in both FIGS. 2 and 3, the columns of openings 200 may form left and right sub-arrays 302; as will become clear from later figures, the openings 200 within these sub-arrays 302 may be extended to depths within the material stack that increase towards the center between the two sub-arrays 302, resulting in a “stadium” structure, with the left and right sub-arrays each forming a half-stadium. For ease of illustration, the left and right sub-arrays 302 are depicted with three columns each; however, as will be understood by those of ordinary skill in the art, the number of columns may vary, depending, among other things, on the number of tiers 106 within the periodic material stack 101 that are to be contacted by the electrical interconnect structure.

FIG. 3 also shows, to both sides of the electrical interconnect region 300, adjacent memory device regions 304 (depicted as arrays of memory cells) that are to be electronically accessed via the electrical interconnect structure. The memory device regions 304 along with the electrical interconnect region 300 may be divided, by one or more slots 306 extending along the x direction and down into the periodic material stack 101 (in the z direction), into multiple laterally adjacent sections 308 extending along the x direction. Within each tier 106 of the periodic material stack 101, the memory cells of each section 308 may be accessed, independently from the cells in other sections 308, by their own respective access line via the associated sub-array of the electrical interconnect structure. While FIG. 3 shows only two sections 308 separated by a single slot 306, it should be understood that the memory device regions 304 and array 300 of vertical openings 200 for the electric interconnect structure may extend farther in the y direction with additional sections.

The following figures illustrate the creation of (sub-)arrays of contact pillars within two adjacent sections 308, but as will be readily apparent to those of ordinary skill in the art, the described processing steps can be straightforwardly applied to larger regions including additional sections 308, resulting in spatially repetitive electrical interconnect structures across the sections 308, with (at least) N contact pillars within each section to facilitate connecting to N tiers 106 within the periodic material stack 101. Further, in the illustrated example, the depths of the contact pillars vary by six tiers 106 between adjacent columns, but it will be obvious how to adjust the process to fewer or more tiers 106 between pillars in adjacent columns. Also, the depicted example shows only three columns of contact pillar trenches in each half-stadium, whereas in typical embodiments, that number may be much higher, e.g., in the high tens of columns of contact pillar trenches.

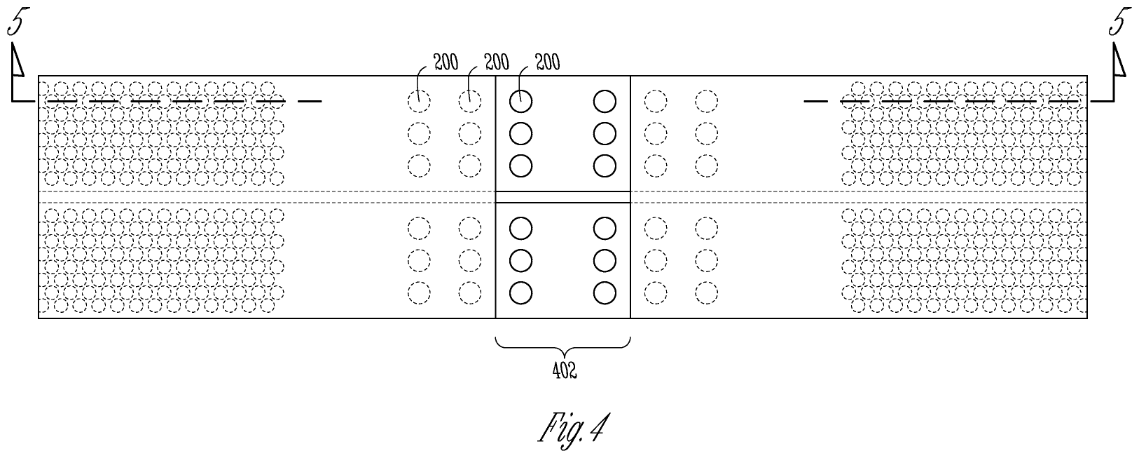

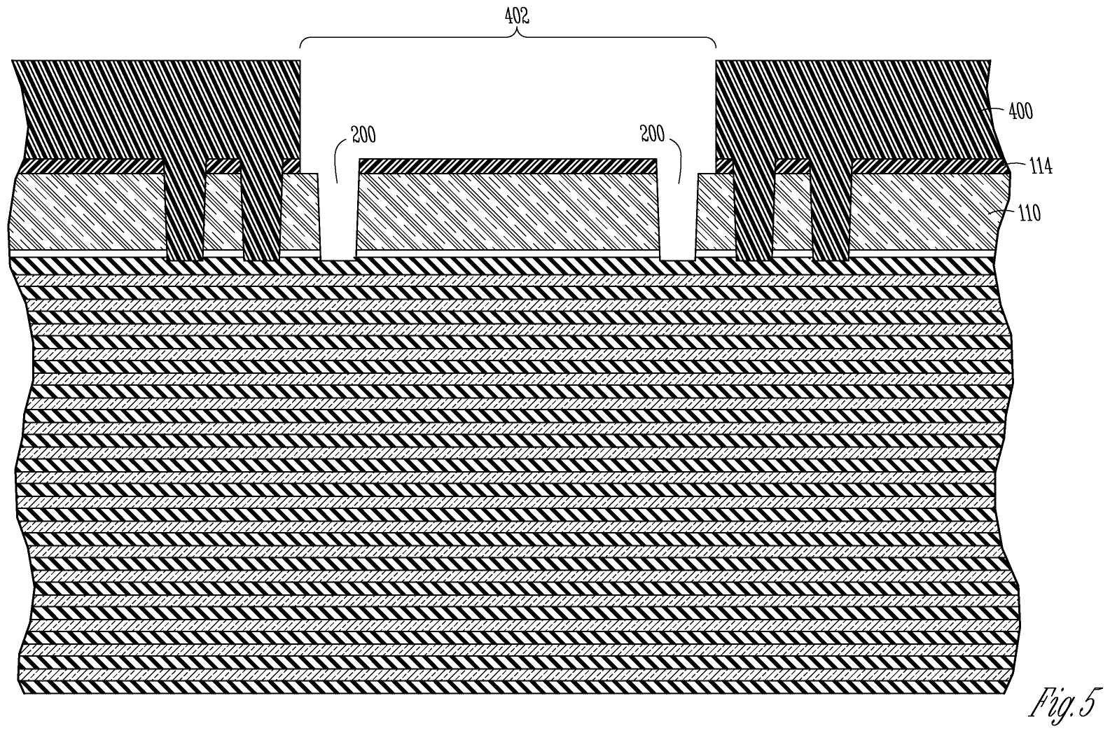

FIGS. 4 and 5 show the material stack 100, in top and cross-sectional views, respectively, with a thick photoresist layer 400 deposited over the patterned hard mask layer 110. The photoresist layer 400 itself is patterned photolithographically (in a similar manner as described above in the context of FIG. 2) to expose a region 402 encompassing a central pair of columns of openings 200 through the hard mask layer 110. The remaining columns and adjacent memory device regions 304 are covered by the photoresist layer 400 (and the openings 200 are filled with photoresist), as indicated by dashed outlines of the openings 200 and the memory cells in the top view in FIG. 4.

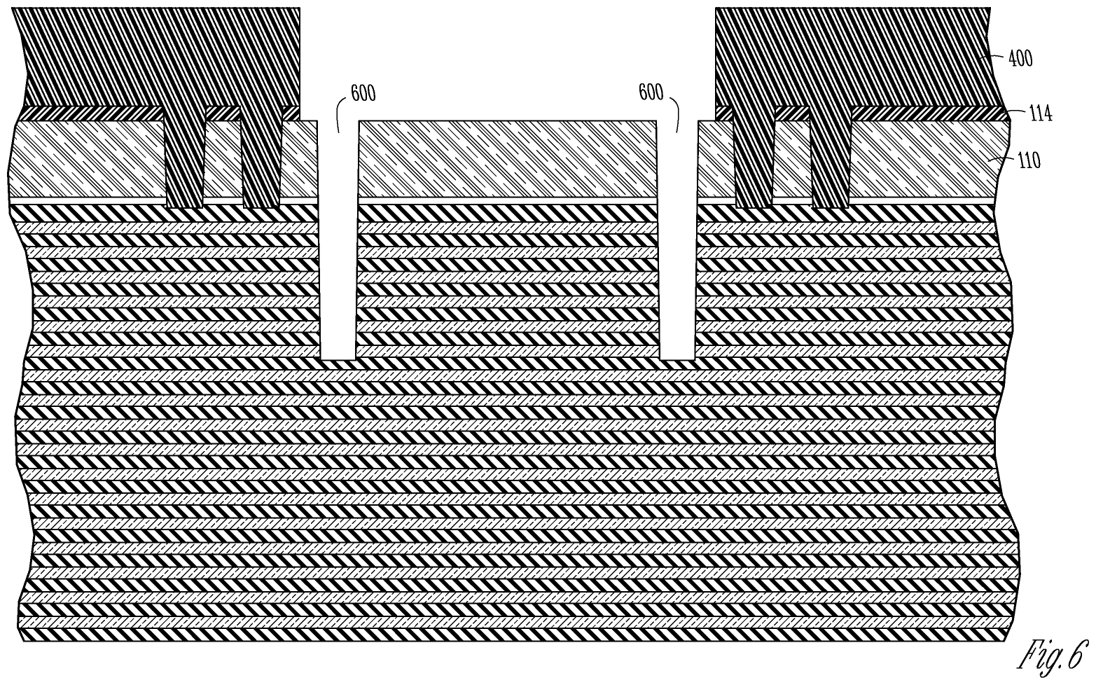

FIG. 6 shows, in cross-sectional view, the structure in the material stack 100 that results from completion of the first first-stage etch cycle. As can be seen, the openings 200 in the exposed region 402 have been extended down into the periodic material stack 101, in the depicted example by six tiers 106, to form the first pair of columns of contact pillar trenches 600. The downward extension of the openings is achieved with a highly directional etching process, such as a high-aspect plasma dry etching. In some examples, reactive ion etching (RIE) with gas chopping (also known as the “Bosch process”) is used. This technique, which is well-known to those of ordinary skill in the art, is itself a cyclical process in which isotropic etching alternates with the deposition of a protection film on the sidewall, using quick gas switching between a suitable etch chemistry, such as, e.g., sulfur hexafluoride (SF₆) plasma, and a suitable sidewall passivation species, such as, e.g., tetracarbon octafluoride (C₄F₈) plasma. When applying gas chopping to the creation of contact pillar trenches 600 in accordance herewith, the etch chemistry itself may alternate between gas plasmas adapted to etch the different materials (e.g., silicon oxide and silicon nitride) making up the periodic material stack 101. As the alternating material layers are etched into, backscattered particles can be detected to serve as a signal that allows keeping track of the current etch depth relative to the material stack. In accordance with various embodiments, to avoid overetch and underetch, an etch through six tiers is achieved by six “one-tier punches,” each corresponding to one gas-switching iteration between the alternating etch chemistries. The etch process may also remove the sacrificial oxide layer 114, but is highly selective to (i.e., does not substantially affect) the underlying hard mask layer 110.

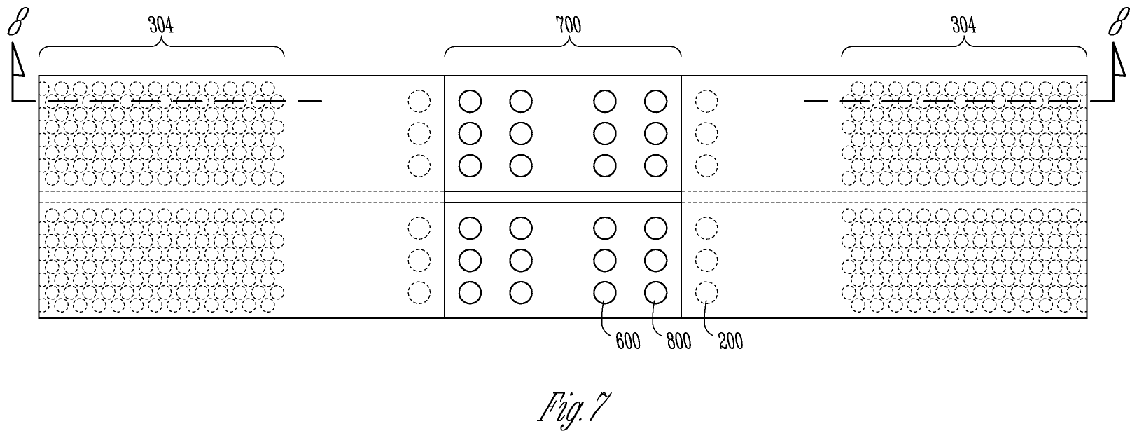

FIG. 7 shows, in top view, the photoresist layer 400 trimmed, for the second first-stage etch cycle, to expose a larger region 700 encompassing an additional pair of columns of openings 200 through the hard mask layer 110, adjacent the central pair of columns of contact pillar trenches 600. The remaining columns and adjacent memory device regions 304 remain covered by the photoresist layer 400. Trimming the photoresist layer to increase the width of the exposed region (from region 402 to region 700) may be achieved by a photoresist trim etch process as known in the art, e.g., a dry etch process using a suitable trimming gas plasma such as, e.g., CF₄/O₂. In addition to etching the photoresist layer 400 laterally, as is desired, the trim etch generally also reduce the thickness of the photoresist layer 400. If the initially deposited photoresist layer 400 is not thick enough to accommodate the requisite number of etch cycles for the desired number of columns of contact pillar trenches within the array without fully depleting, photoresist may be repeatedly reapplied and patterned throughout the first stage.

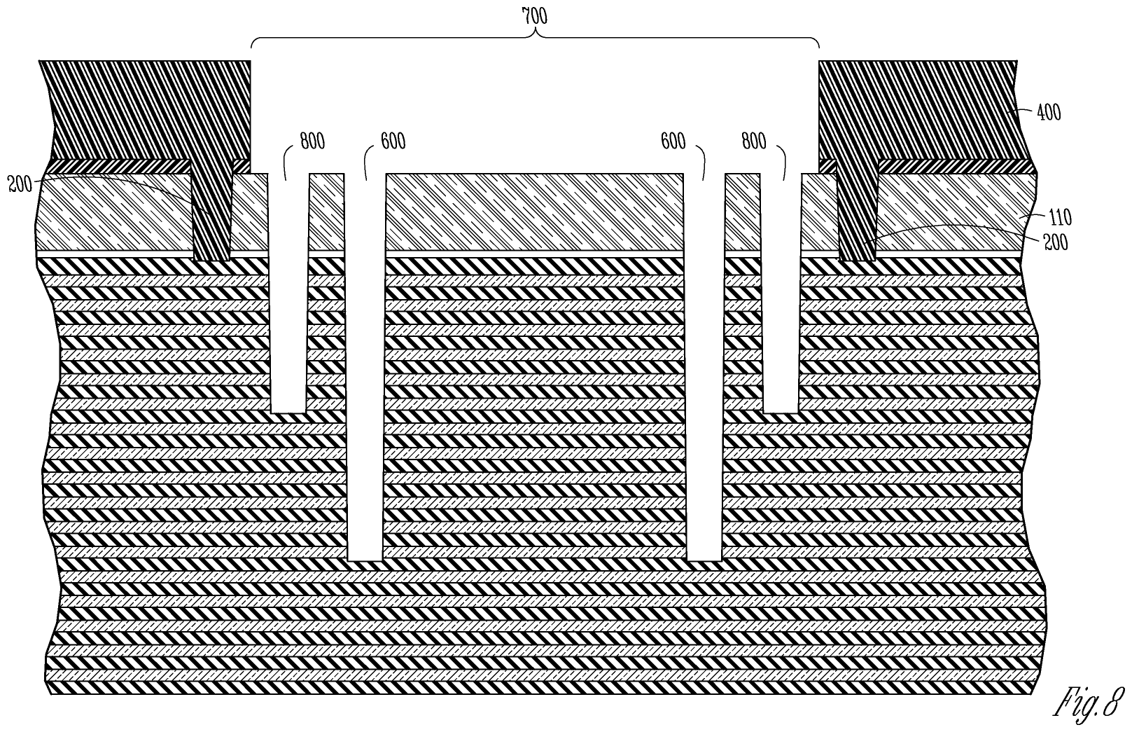

FIG. 8 shows, in cross-sectional view, the structure in the material stack 100 that results from completion of the second first-stage etch cycle. The newly exposed openings 200 in the exposed region 700 have been extended down into the periodic material stack 101 by six tiers 106 to form a second pair of columns of contact pillar trenches 800, while the previously etched contact pillar trenches 600 have simultaneously been extended another six tiers 106 down.

The process of trimming the photoresist layer 400 and etching into the periodic stack 101 to form and iteratively extend contact pillar trenches (e.g., 600, 800) can be repeated for as many cycles as needed to create the desired number of columns of contact pillar trenches and reach the desired depth within the periodic stack 101. Since the last column of contact pillar trenches is not etched until the second stage, an array of m/2 columns of contact pillar trenches per half-stadium, as used to ultimately establish electrical connections d×m/2=n×m tiers deep (where d=2n is the number of tiers etched in each cycle), is created with (m/2−1) etch cycles in the first stage. While the figures depict the case of m/2=3 for ease of illustration, the number of columns is usually significantly greater in practice. In some cases, the originally deposited photoresist layer 400 lasts for only a fraction of the total number of etch cycles, and accordingly, new photoresist layers are applied repeatedly after a certain number of cycles.

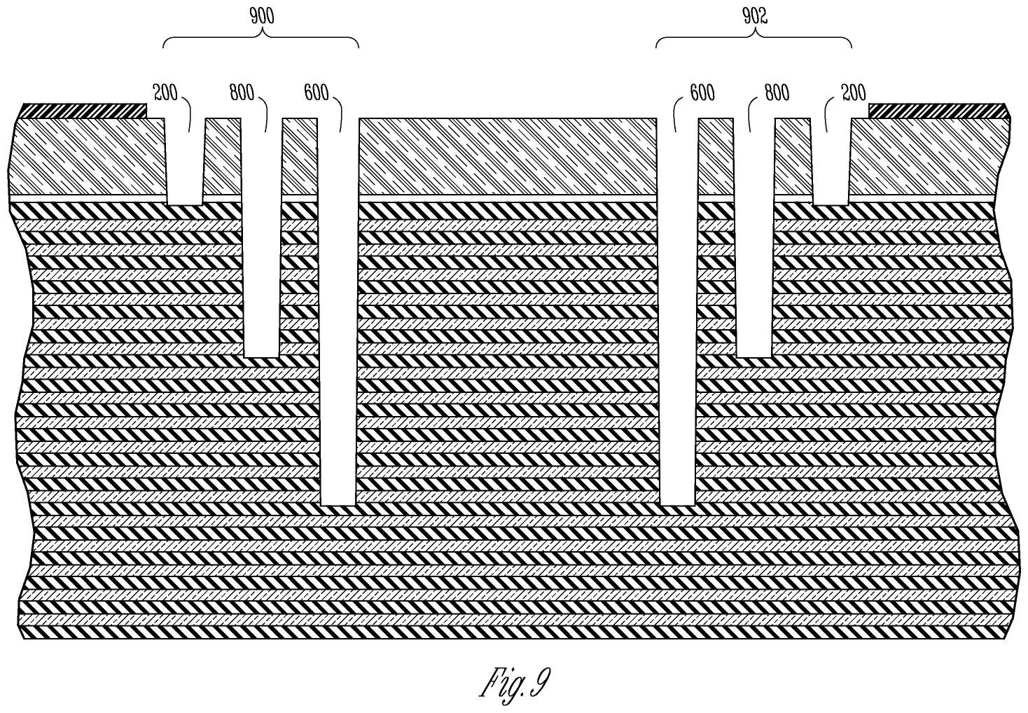

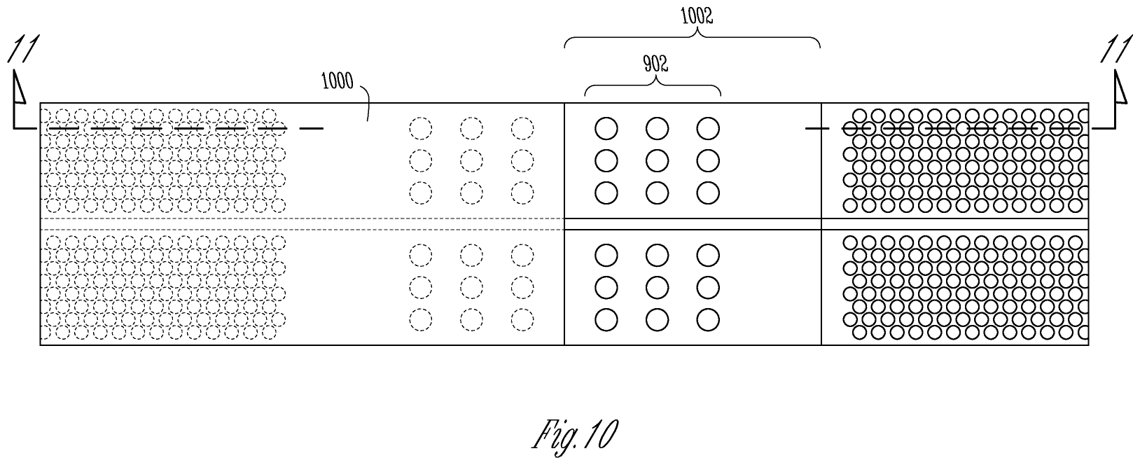

FIG. 9 shows, in cross-sectional view, the stadium structure of contact pillar trenches in the material stack 100 after completion of the last etch cycle in the first stage that is applied symmetrically to the left and right sub-arrays 302. The stadium is formed, in this example, by trenches contact pillar trenches 600, 800, and the outermost column of openings 200 that are yet to be extended into the periodic stack 101, which are hereinafter all referred to as “contact pillar trenches” and collectively designated by reference number 900 for the left half-stadium and by reference number 902 for the right half-stadium. In FIG. 10, the portions of the photoresist layer 400 still remaining after the last contact-pillar-trench etch cycle have been removed (e.g., etched away). In the next processing steps, as depicted in FIGS. 10-12, the contact pillar trenches 902 in the right sub-array will be further extended downward by n/2=3 tiers 106 to form two half-stadium structures with contact pillar trenches that are offset in depth by half the number of tiers 106 as between adjacent columns of contact pillar trenches within each half-stadium.

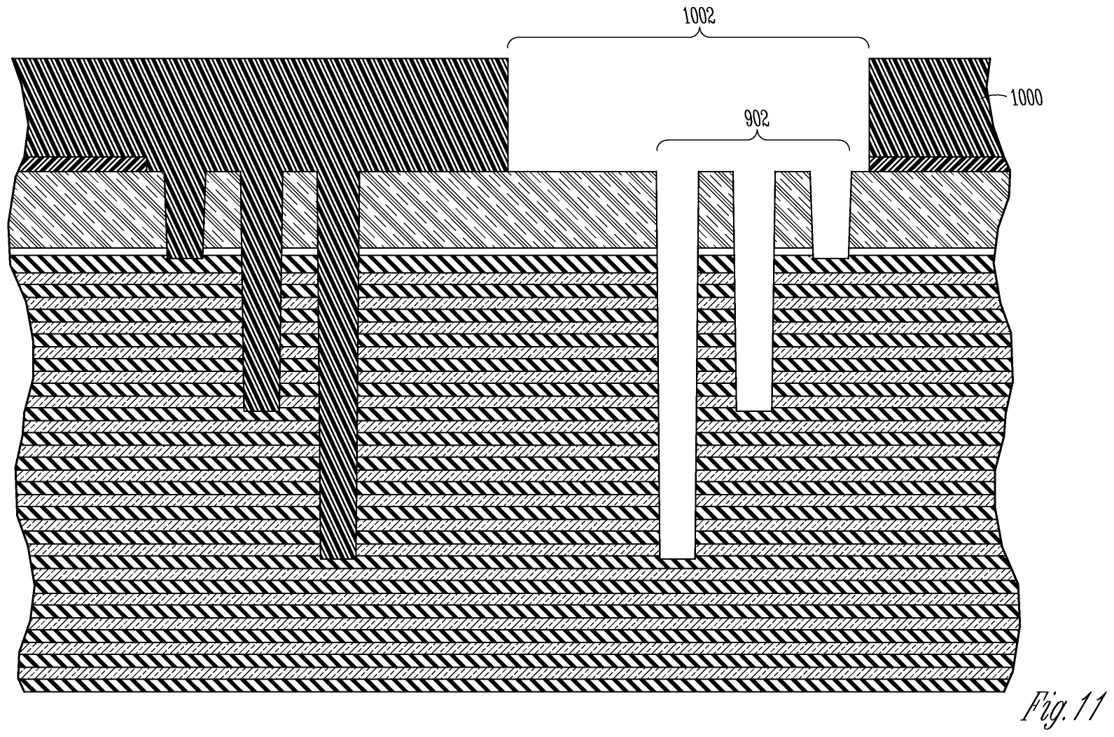

FIGS. 10 and 11 show, in top and cross-sectional views, respectively, a new photoresist layer 1000 deposited over the material stack 100, photolithographically patterned (in a similar manner as described above in the context of FIG. 2) to expose a region 1002 encompassing one half-stadium of contact pillar trenches, in the depicted example the right contact pillar trenches 902. The other half-stadium of contact pillar trenches 900 and the memory device regions 304 to both sides are covered by the photoresist layer 1000, as indicated by dashed outlines of the trenches 900 and the memory cells in the top view in FIG. 10.

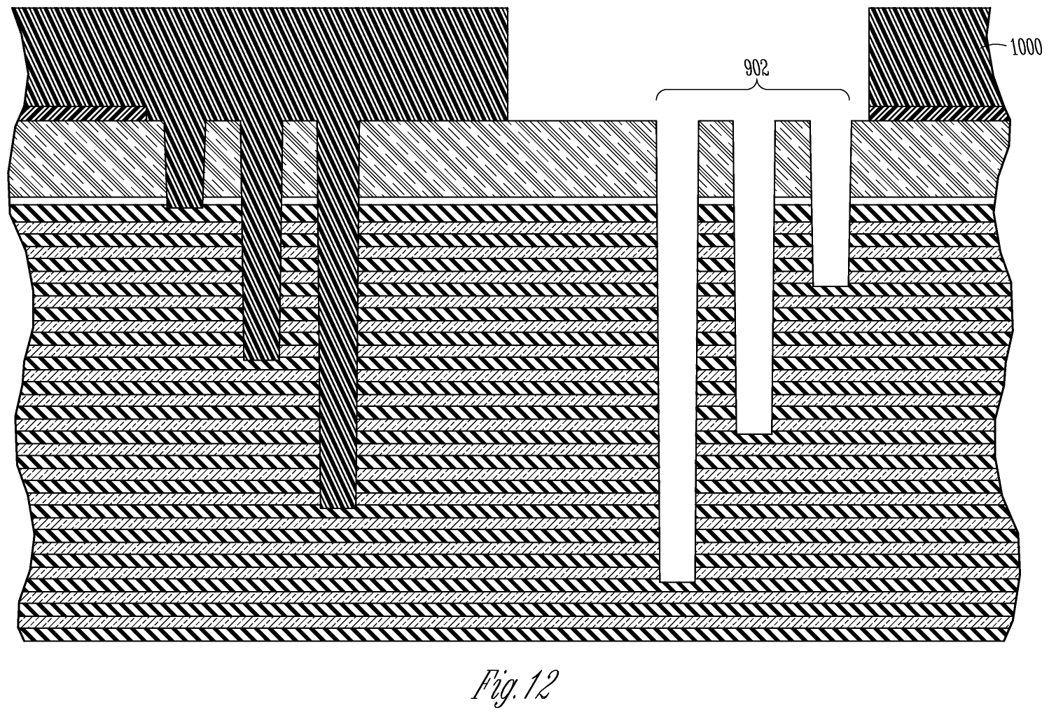

FIGS. 12 shows, in cross-sectional view, the structure in the material stack 100 that results from completion of a single additional first-stage etch cycle extending the exposed contact pillar trenches 902 and openings three tiers 106 down into the periodic material stack 101. This etch cycle may use the same etch technique as employed in preceding etch cycles (e.g., DRIE with gas chopping, as described above with reference to FIG. 6), adjusted merely in the number of gas-switching iterations to reduce the number of one-tier punches, and thus the number of tiers 106 etched, to three in this example. Following this additional etch cycle, the photoresist layer 1000 (still shown in FIG. 12) is removed, which completes the first stage of etching.

At the end of the first stage, the array of contact pillar trenches 900, 902 created in the material stack 100 is translationally symmetric in the y-direction in that it includes multiple structurally identical rows (extending along the x-direction) of trenches. Each such row forms two half-stadium configurations with pillar depths varying by d (in the depicted example, six) tiers 106 between adjacent columns and by d/2 (in the depicted example, three) tiers 106 between corresponding columns in the two half-stadiums. Collectively, the m columns of contact pillar trenches reach every third tier between 0 and 3×(m−1). To also reach the intervening tiers, the contact pillar trenches 900, 902 are further extended, in a second stage of etch cycles, to create varying depths along the columns, and between the rows, of contact pillar trenches. In preparation for the second stage, a new thick photoresist layer is deposited over the hard mask layer 110 of the material stack 100. This photoresist layer is patterned or trimmed, preceding each etch cycle of the second stage, using the same photolithographic patterning and trim etch techniques as described above in the context of FIGS. 2 and 7.

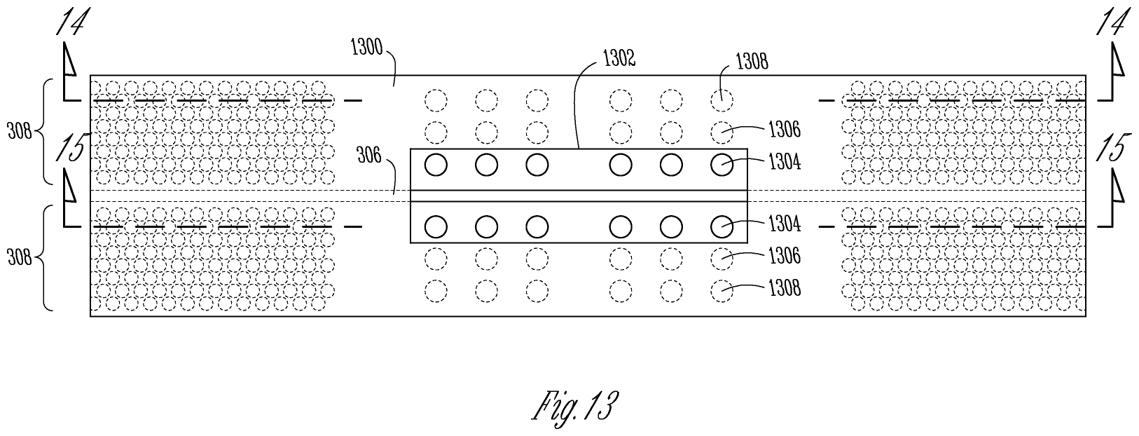

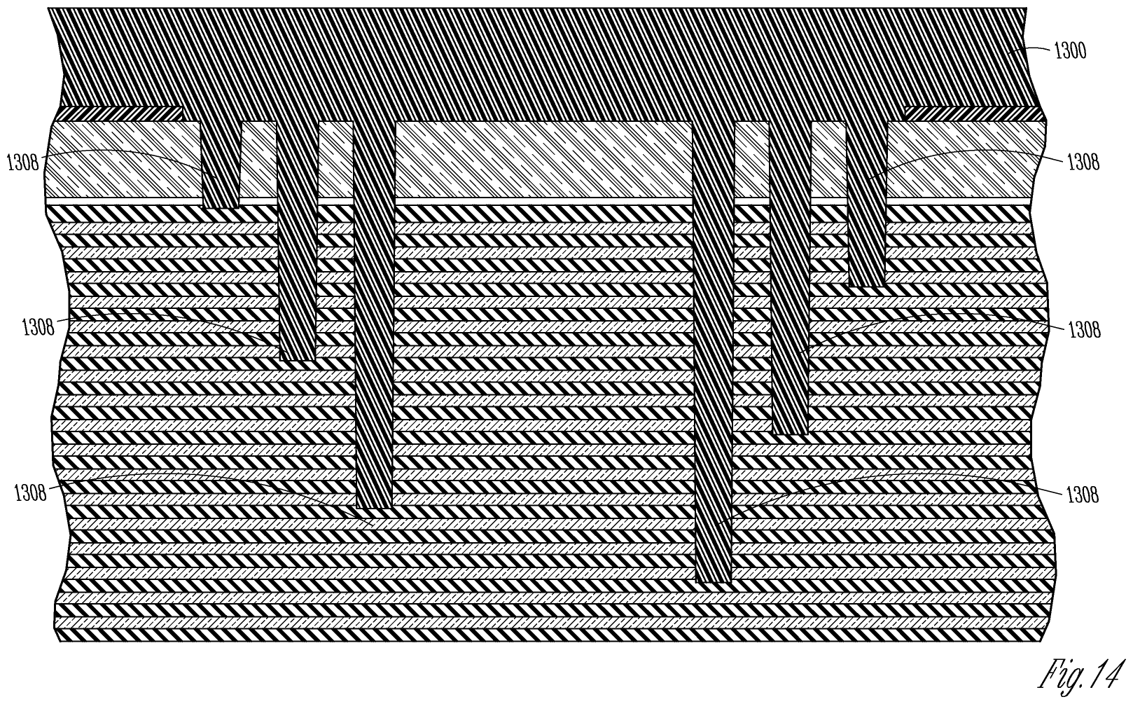

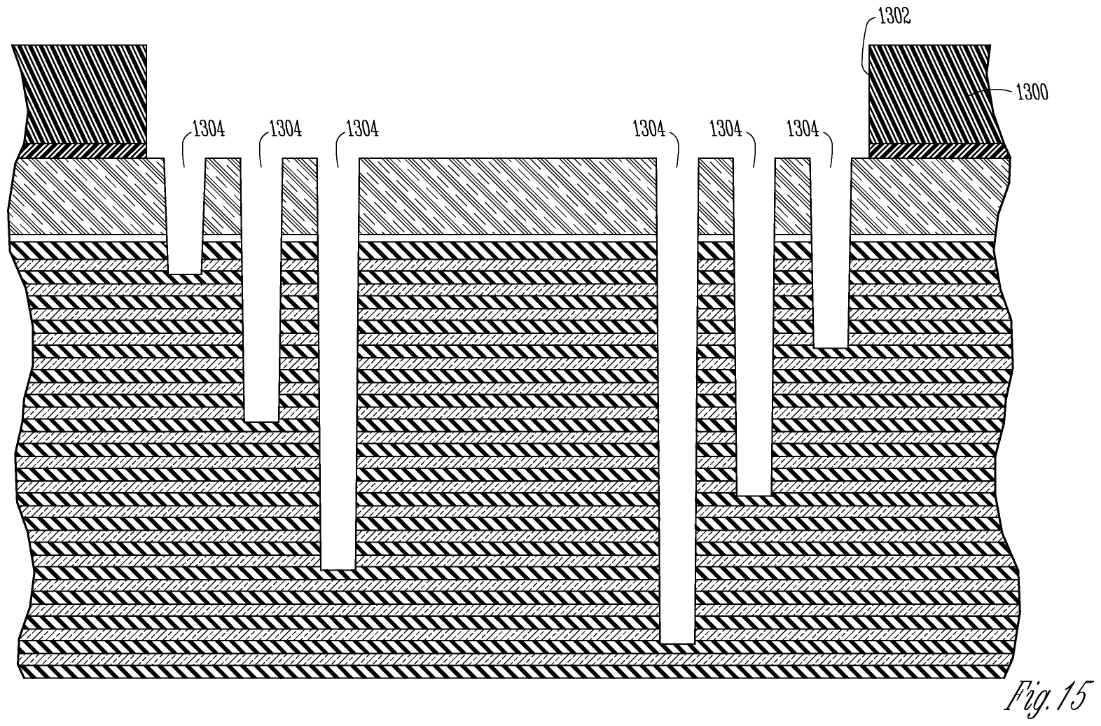

FIG. 13 shows the material stack 100, in top view, with a new photoresist layer 1300 photolithographically patterned, in preparation for the first etch cycle of the second stage, to expose a horizontal region 1302 encompassing two rows of contact pillar trenches 1304 (only one contact pillar trench in each row being labeled to avoid obfuscation), in two adjacent sections 308 of the memory device and electrical interconnect regions 304, 300, placed symmetrically about the slot 306 separating the two sections 308. The remaining rows of contact pillar trenches 1306, 1308 (only one contact pillar trench in each row being labeled) as well as the memory device regions 304 remain covered by photoresist. Note that, if the material stack 100 includes additional sections 308 in the y-direction, the same patterning step may be used to simultaneously expose one row in each of the additional sections, e.g., paired symmetrically about every other slot 306 separating neighboring sections 308. (In principle, it is also possible to create the electrical interconnect structure in only a single section 308, in which case the photoresist layer 1300 is patterned to expose only one row preceding the first second-stage etch cycle.) FIG. 13 also indicates the locations along the y-direction of two cross sections (in the x-z plane) through the material stack 100, shown in FIGS. 14 and 15.

FIG. 14 shows the material stack 100, in cross-sectional view, for a row of contact pillar trenches 1308 (or, similarly, 1306) that is covered by the new photoresist layer 1300 following the initial patterning. As can be seen, the photoresist fills the contact pillar trenches 1308 in the periodic stack 101. The first second-stage etch cycle does not affect this row of contact pillar trenches 1308.

FIG. 15 shows the material stack 100, in cross-sectional view, for a row of contact pillar trenches 1304 in the exposed region 1302 following the first etch cycle of the second stage. As a careful comparison of the contact pillar trenches 1308, 1304 between FIGS. 14 and 15 reveals, each of the contact pillar trenches 1304 in the exposed row has been etched one further tier 106 down, in a one-tier punch, which may use the same general etch technique as employed in the first-tier etch cycles (e.g., DRIE with gas chopping, as described above with reference to FIG. 6), shortened to a single gas-switching iteration.

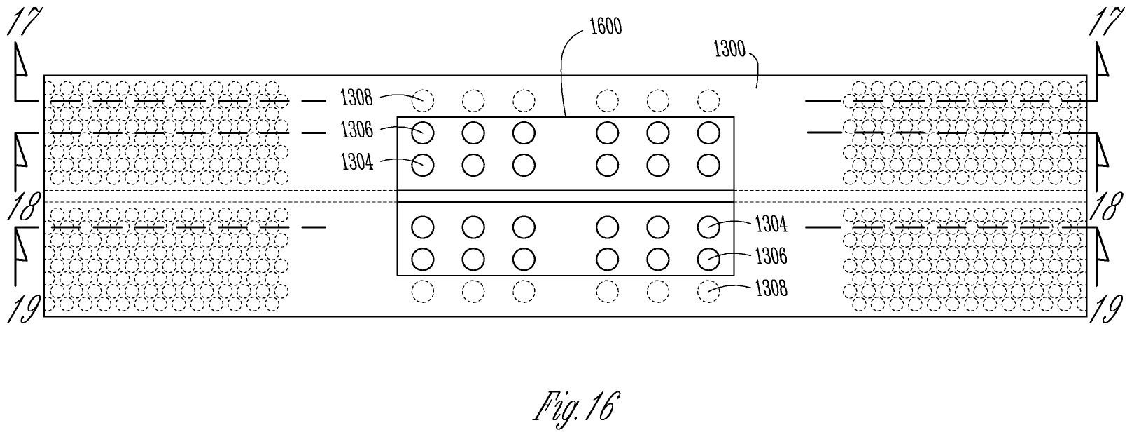

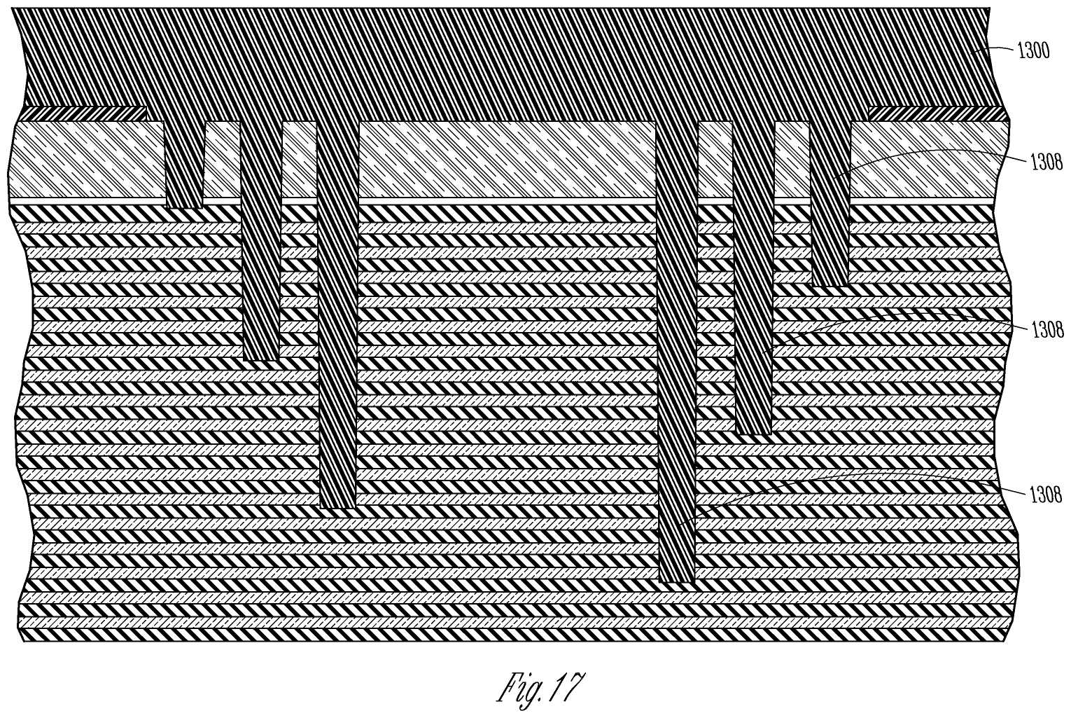

FIG. 16 shows the material stack 100, in top view, after the new photoresist layer 1300 has been trimmed, in preparation for the second etch cycle of the second stage, to expose a larger region 1600 encompassing an additional pair of rows of contact pillar trenches 1306 to both sides of and adjacent to the previously exposed rows of contact pillar trenches 1304. The remaining rows of contact pillar trenches 1308 and the adjacent memory device regions 304 remain covered by the photoresist layer 1300. FIG. 16 also indicates the locations along the y-direction of three cross sections (in the x-z plane) through the material stack 300, shown in FIGS. 17-19.

FIG. 17 shows, in cross-sectional view, a row of contact pillar trenches 1308 that is still covered by the photoresist layer 1300 following the trim etch. These trenches 1308 remain unaffected by the second etch cycle, and the cross section is, accordingly, identical to that of FIG. 14.

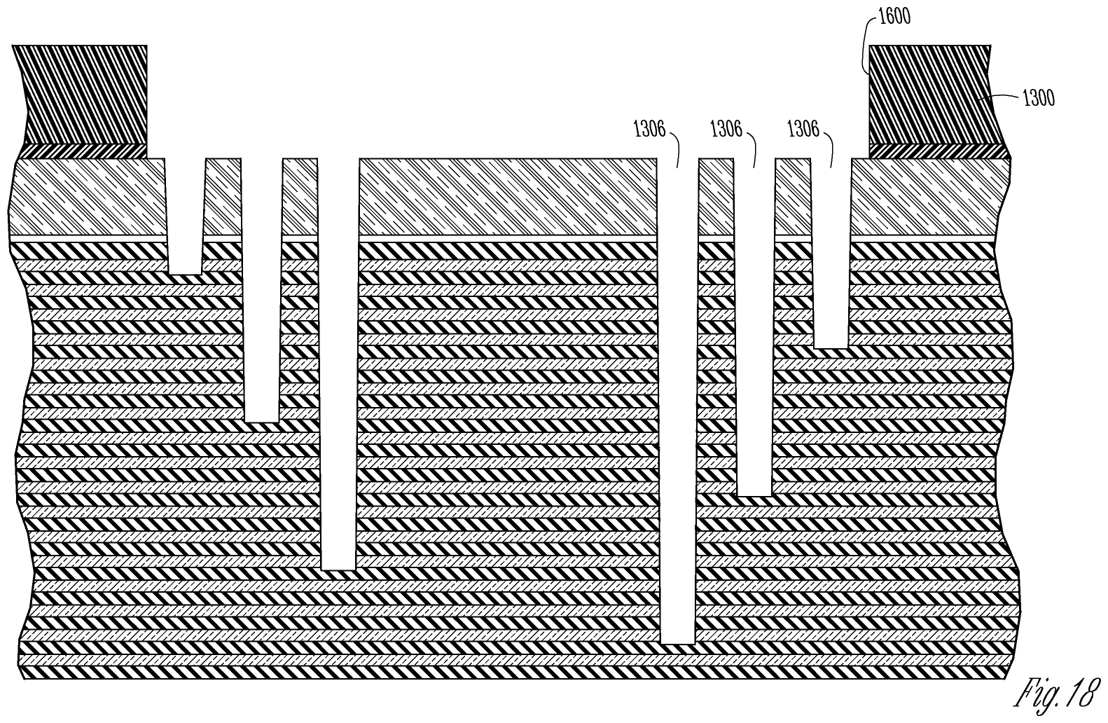

FIG. 18 shows, in cross-sectional view, a newly exposed row of contact pillar trenches 1306 in the exposed region 1600 following the second etch cycle (or second “one-tier punch”) of the second stage. Each of the contact pillar trenches 1306 in the exposed row has been etched one further tier 106 down, such that this row of trenches 1304 now looks like the first pair of rows of contact pillar trenches 1306 at the end of the first second-stage etch cycle, as depicted in FIG. 15.

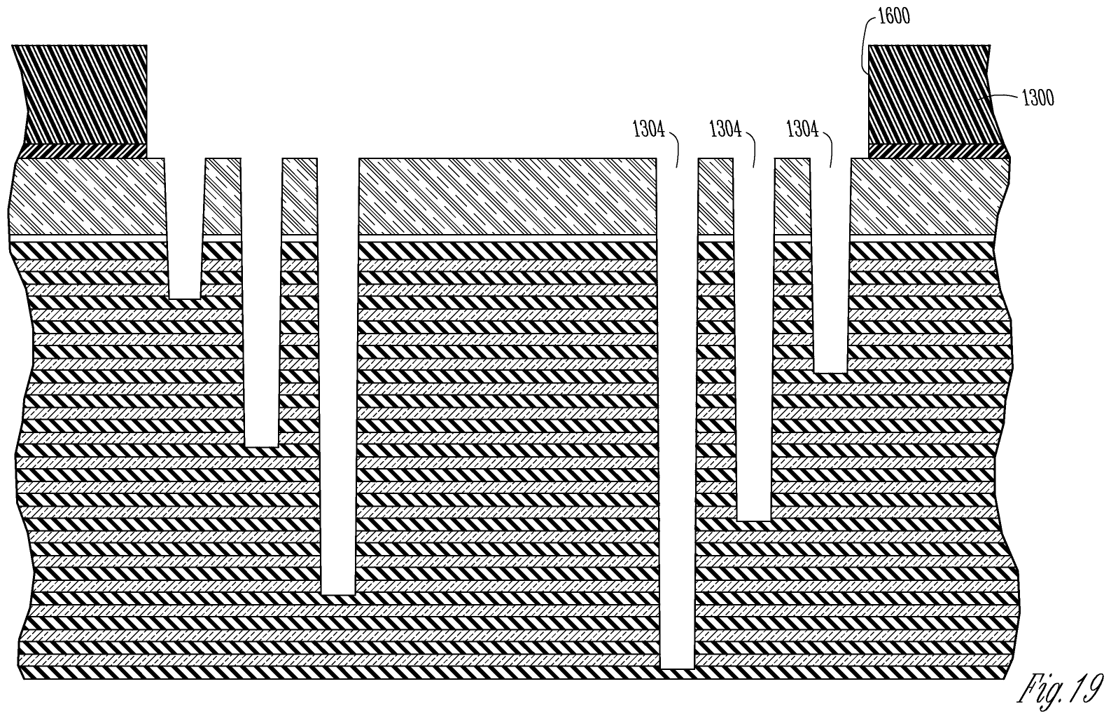

FIG. 19 shows, in cross-sectional view, the previously exposed row of contact pillar trenches 1304 in the exposed region 1302 following the second etch cycle of the second stage. Each of the contact pillar trenches 1304 has been etched yet another tier 106 down, such that all trenches 1304 in this row are now one tier deeper than at the end of the first second-stage etch cycle (as shown in FIG. 15) and two tiers deeper than at the end of the first stage of etch cycles (as shown in FIG. 14).

For the depicted example of an array including m/2=3 columns of contact pillar trenches per half-stadium, differing by d=6 six tiers between adjacent columns in a given row with a three-tier offset between half-stadiums, (d/2-1)=2 etch cycles complete the second stage. As can be seen from FIGS. 17-19, the three rows of contact pillar trenches 1304, 1306, 1308 in each section 308 now vary in depth by one tier between adjacent rows, such that the contact pillar trenches of all rows and columns together extend to depths corresponding to a total of d/2×m=n×m=18 adjacent tiers 106. (At this point, the contact pillar trenches end just above the first through eighteenth tier. In a subsequent punch-through etch, they will be extended to access these eighteen tiers.) As will be readily appreciated by those of ordinary skill in the art, if the number d of tiers per cycle etched in the first stage differs from six, or if the array includes only one half-stadium, the number of rows per section and of etch cycles in the second stage is adjusted accordingly. For example, for full stadium structures with d=8 tiers between adjacent columns and a four-tier offset between half-stadiums, each section will include d/2=4 rows to be etched in (d/2−1)=3 three etch cycles in the second stage. For arrays that include only a half-stadium with n=d tiers between adjacent columns, each section will include n rows to be etched in (n−1) etch cycles in the second stage.

Following the creation of the stadium structure of contact pillar trenches and removal of the remaining photoresist (including from contact pillar trenches 1308) and sacrificial oxide layer 114, the electrical interconnect structure will be formed in a series of process steps that involve replacing one of the material layers in each accessed tier 106 of the period stack 101 with an electrically conductive material (e.g., to serve as the access lines), lining the side walls of the contact pillar trenches with an electrical insulator material and punch them through to the electrically conductive layer of the respective tiers to be contacted, and finally filling the contact pillar trenches with an electrical conductor material to form contact pillars electrically connected to the conductive layers in each accessed tier 106. In some embodiments, the electrical interconnect structure is formed in the electrical interconnect region 300 after the memory array has been created in the memory device region(s) 304. In other embodiments, some of the above-described steps are applied simultaneously to the electrical interconnect region 300 the memory device region(s) 304 adjacent the electrical interconnect region 300 to form the memory array and electrical interconnect structure partially in parallel. For example, the replacement of one of the material layers in each tier with an electrically conductive material forming the access lines may be performed over the entire memory device and electrical interconnect regions 304, 300. Further, in some examples, the memory array includes conductive pillars (e.g., serving as ground pillars or data line pillars) that can be created in corresponding trenches in the memory device regions(s) 304 using some processing steps (e.g., lining the walls with an insulator and then filling the trenches with a conductor) that may be shared with the electrical interconnect structure. It is also possible in principle to form the electrical interconnect structure in a material stack that already includes alternating conducting and non-conducting layers, e.g., a periodic stack of insulating oxide and conducting polysilicon layers.

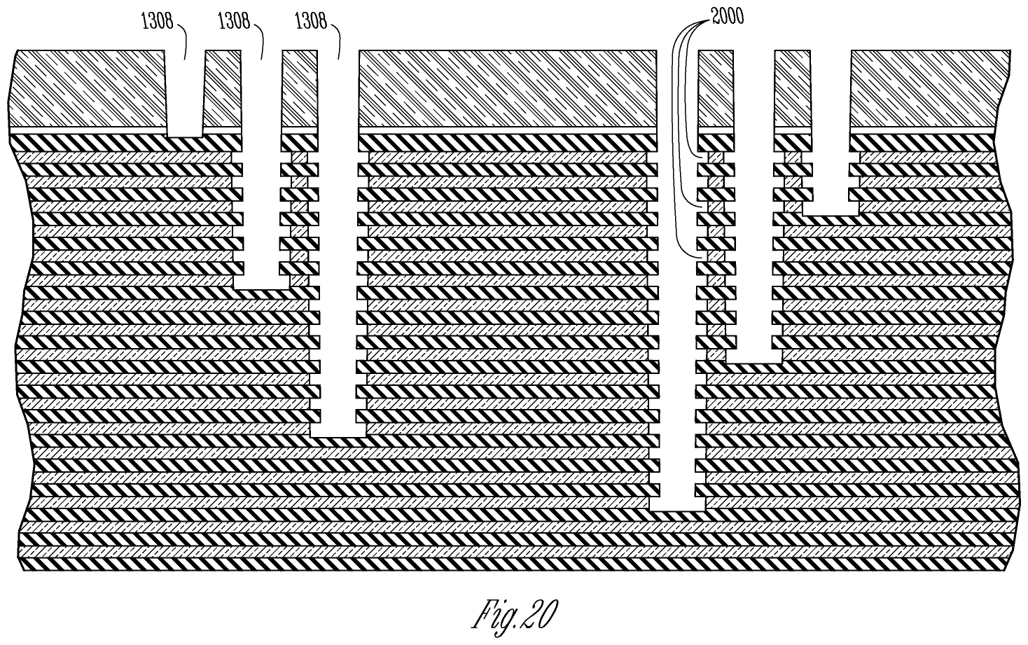

FIGS. 20-28 illustrate the steps for creating contact pillars in the stadium of contact pillar trenches with a series of cross-sectional views through the row of contact pillar trenches 1308; the same steps are, of course, applied simultaneously to the remaining rows of contact pillar trenches 1304, 1306.

FIG. 20 shows, in cross-sectional view, a row of contact pillar trenches 1308 after recesses 2000 extending from the contact pillar trenches 1308 have been etched into the material layers 104 (e.g., silicon nitride layers) within the tiers 106 of the periodic stack 101 that are subsequently to be replaced with an electrically conductive material (e.g., tungsten). These recesses may be formed using a wet etch process with any etchant that can remove the silicon nitride of layer 104 selectively to the oxide (or other material) of the intervening layers, e.g., hot phosphoric acid.

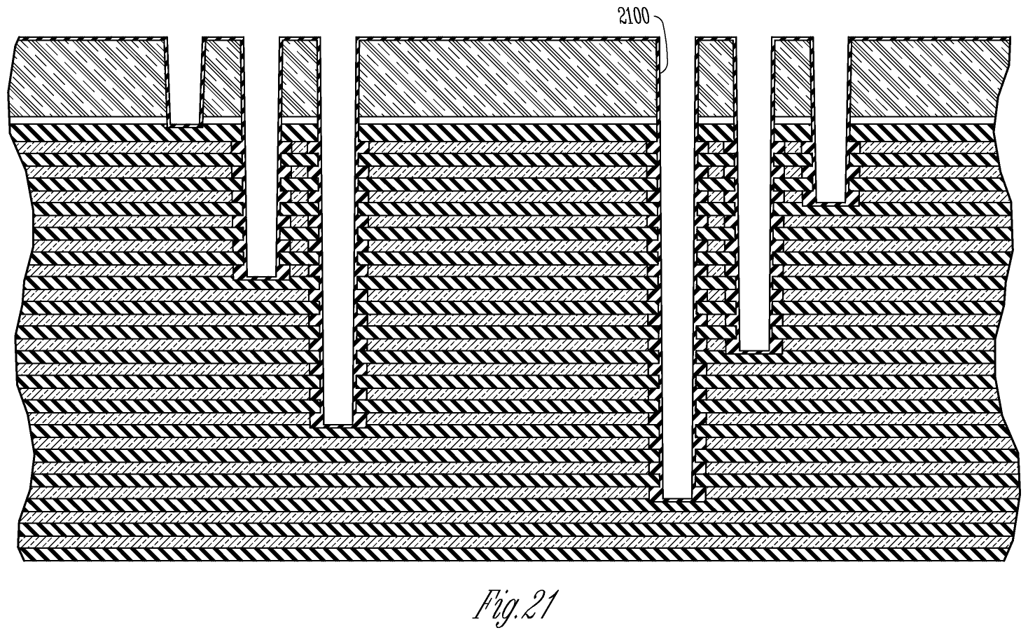

FIG. 21 shows, in cross-sectional view, the row of contact pillar trenches 1308 after the walls of the contact pillar trenches 1308 have been lined, and the recesses 2000 have been filled, with an electrically insulating material (e.g., oxide). The resulting liner 2100 has a thickness sufficient to later electrically insulate the conductive pillars to be formed in the contact pillar trenches from the conductive layers in the periodic material stack, while not being too thick to subsequently punch through the liner at the bottom of the contact pillar trenches 1308. In some examples, the liner thickness is between 80 nm and 120 nm.

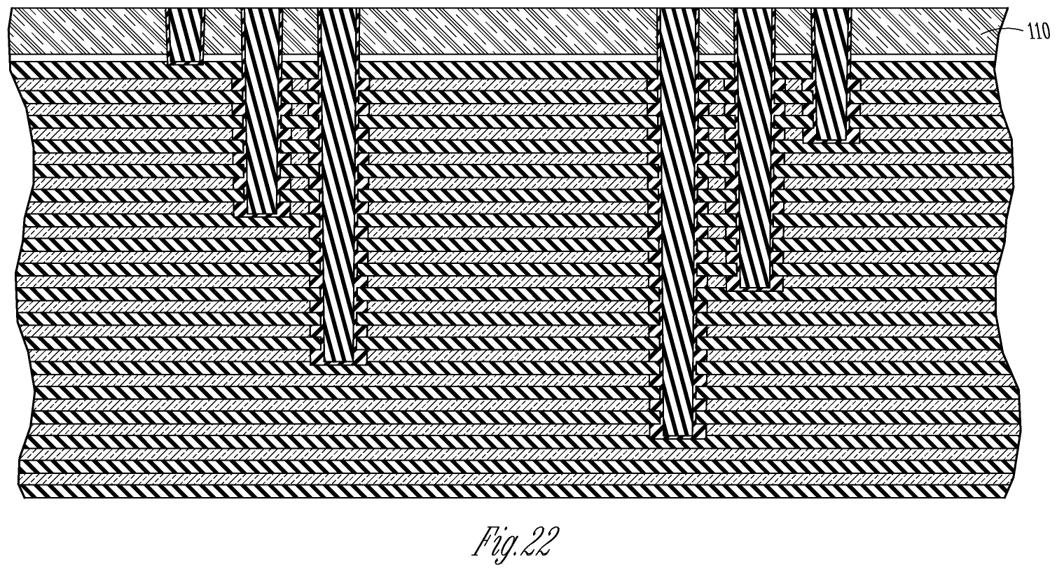

FIG. 22 shows, in cross-sectional view, the row of contact pillar trenches 1308 after the lined trenches 1308 have been filled with a sacrificial fill material (e.g., polysilicon, silicon nitride, aluminum oxide, tungsten, carbon, etc.).Further, as can be seen, the material has been planarized, e.g., by chemical mechanical polishing (CMP), a hybrid process that combines chemical etching and abrasive polishing. In the process, the portion of the insulating liner 2100 that was deposited over the hard mask layer 110, and a portion of the hard mask layer 110 itself, have been removed.

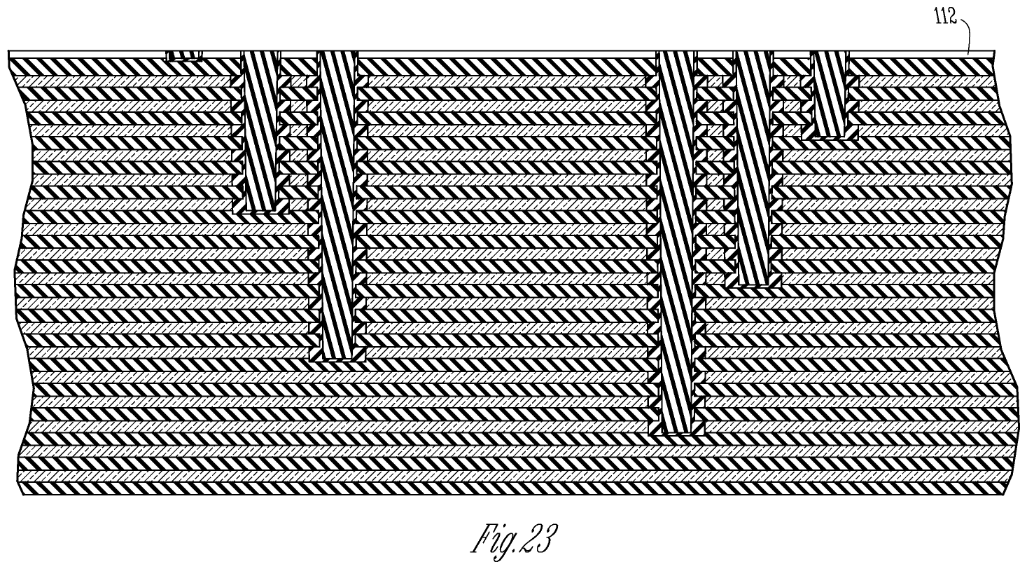

FIG. 23 shows, in cross-sectional view, the row of contact pillar trenches 1308 after complete removal of the hard mask layer 110, e.g., by CMP, conventional chemical etching, or a mechanical process. The layer 112 (which may be, e.g., a carbon nitride layer) serves as an etch stop layer in this process.

FIG. 24 shows, in cross-sectional view, a new material stack resulting from deposition of a dielectric layer 2400 and replacement of the non-conductive (e.g., silicon nitride) layers 104 by electrically conductive material layers 2402 in a replacement gate process. Access to the layers to be replaced can be provided via slits or openings formed in the original material stack. The replacement process generally involves complete removal of the original sacrificial material layer 104 by wet etching with a highly selective etchant that etches the other material layers 102 in the stack only minimally if at all, and then back-filling the metal into the resulting space through the openings or slits. In the resulting new periodic material stack 2404, the metal layers 2402, which may form the access lines (and, in the memory device regions 304, the associated transistor gates), alternate with the insulating material layers 102 of the original periodic stack 101, forming tiers 2406 at the same locations as the original tiers 106.

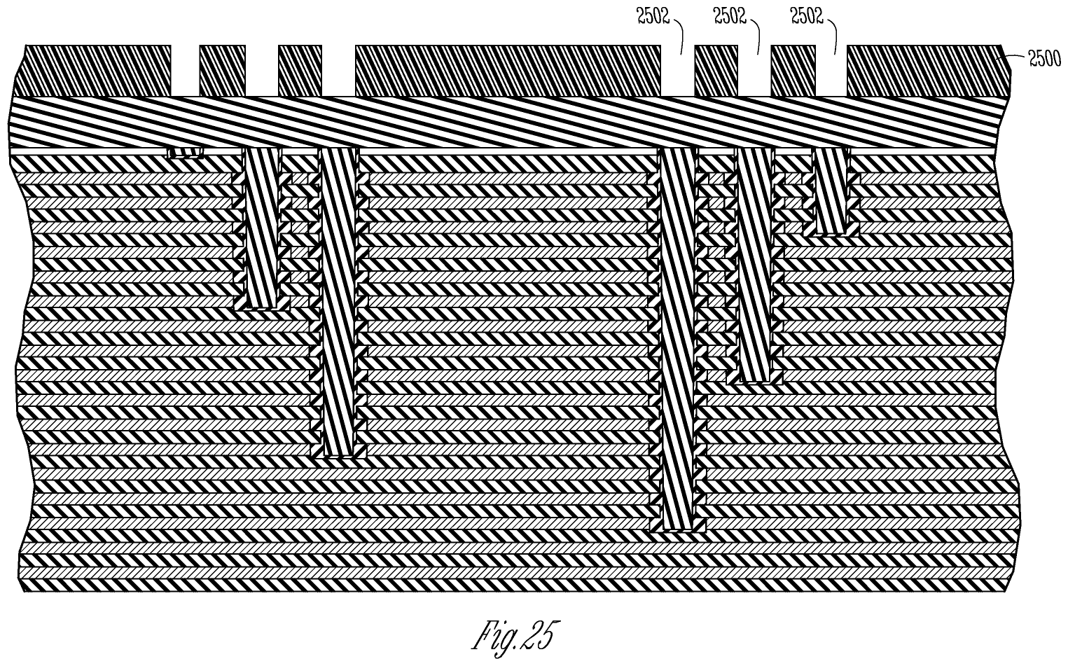

FIG. 25 shows, in cross-sectional view, the new material stack with a photoresist layer 2500 deposited over the dielectric layer 2400. The photoresist layer 2400 is patterned to form openings 2502 directly above the SAC-filled contact pillar trenches 1308.

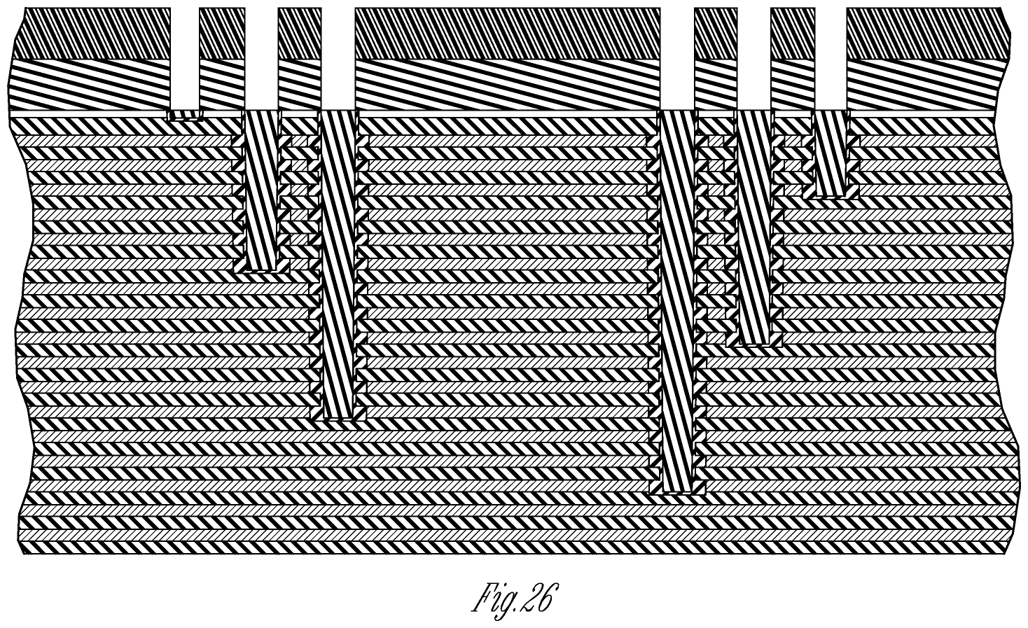

FIG. 26 shows, in cross-sectional view, the openings 2502 in the photoresist layer 2500 extended down through the top dielectric layer 2400 to the SAC-filled contact pillar trenches 1308. The SAC fill itself acts as an etch stop in this process.

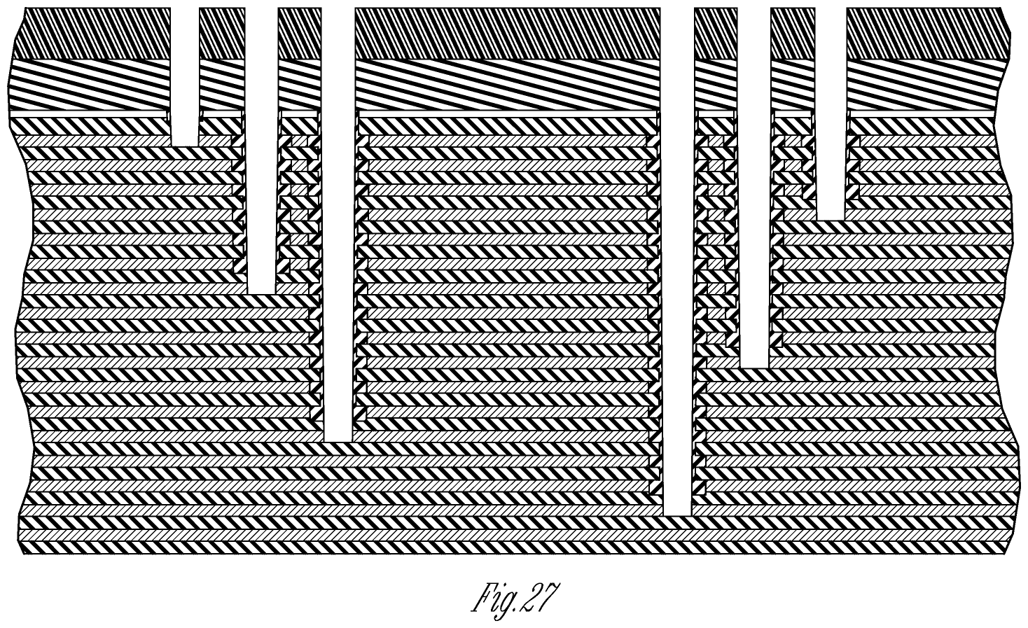

FIG. 27 shows, in cross-sectional view, the contact pillar trenches 1308 reopened by exhuming the SAC fill from the contact pillar trenches 1300, and extended by a one-tier punch through the insulating liner 2100 and the insulating layer 102 below into the metal layer 2402 of the immediately adjacent tier. The one-tier punch may use the same general etch technique as employed in the first-tier and second-tier etch cycles, with a single gas-switching iteration. Following the punch through the insulating liner 2100 and layer 102 into the electrically conductive layer 2402 directly below, the contact pillar trenches collectively extend to the conductive layers 2402 of the first through N-th tier (with N=n×m, n being the number of consecutive tiers accessed in each column, and m being the number of columns in the array).

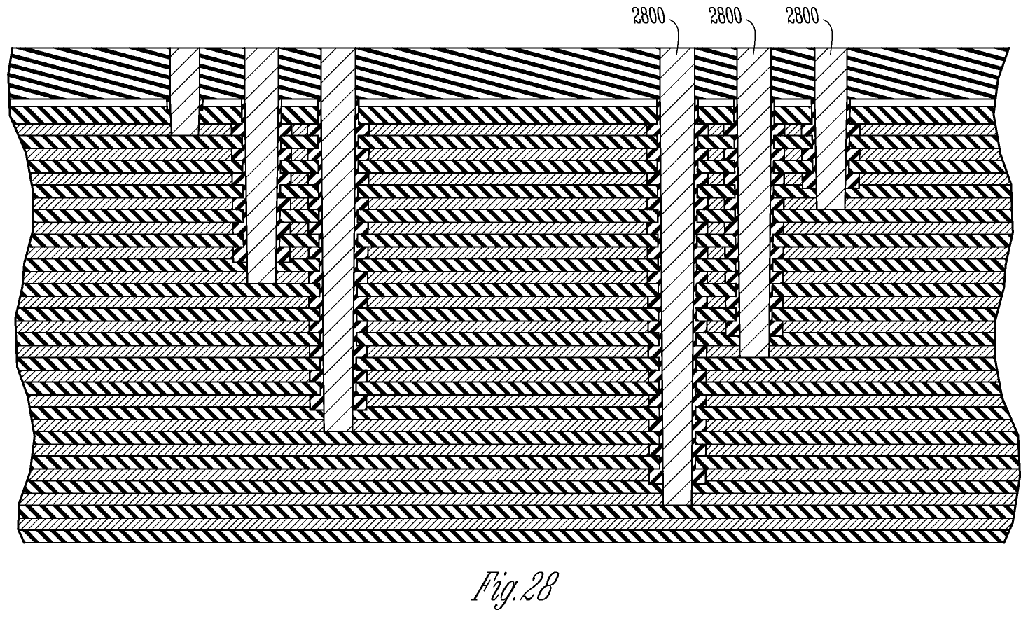

FIG. 28 shows, in cross-sectional view, the previously re-opened contact pillar trenches 1308 filled with an electrically conductive material, such as tungsten, copper, or some other metal to form the contact pillars 2800. The photoresist layer 2500 has been removed from the stack, e.g., by a CMP process, followed by an oxide strip process to clean up any resist and polymer residue.

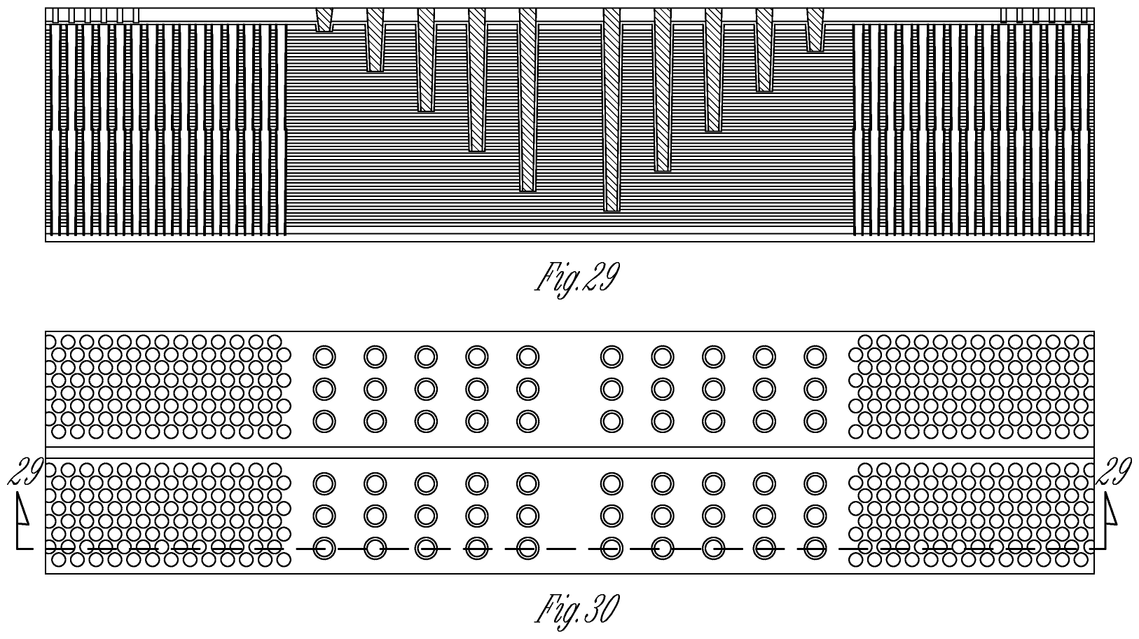

FIGS. 29 and 30 show, in cross-sectional and top views, respectively, the final electric interconnect structure alongside the adjacent memory arrays. In the depicted example, the electric interconnect structure is shown with five columns per half stadium (rather than three as in FIGS. 2-28). Within each half stadium, the pillar depths vary by six tiers between adjacent columns. Between the half stadiums, columns of pillars otherwise mirroring each other are offset in depth by three tiers. Thus, the pillars within any given row collectively extend to every third tier within the stack. The different rows of pillars share the same relative depths between pillars along the rows, but are offset by one tier between adjacent rows to provide access to the intervening tiers. As will be readily appreciated by those of ordinary skill in the art, embodiments may differ in the number of rows, columns, and offsets in depth therebetween form the specific depicted example. As previously noted, the number of columns will in practice typically be greater than depicted.

In an example application, the described electrical interconnect structure is used as part of a 3D memory device. In general, a 3D memory device includes a 3D array of memory cells with associated data lines, access lines, and connections to electrical ground, along with peripheral circuitry (including, e.g., address decoders for the access and data lines, pre-charge circuits, sense amplifiers, data buffers and buses, and timing and control circuitry) to operate the memory array. Each two-dimensional tier of memory cells within the 3D array may be formed within a respective tier of a periodic material stack, and may encompass a number of layers or sublayers within the tier that collectively form a device level. The tiers within the material stack may also include additional layers forming separation levels between the device levels. The peripheral circuitry may be formed alongside the memory array in adjacent areas of the material stack, or alternatively in separate layers above or below the memory array. The electrical interconnect structure described herein provides a beneficial means to establishing electrical connections between parts of the peripheral circuitry and the 3D memory array. In particular, the electrical interconnect structure can be used to electrically access the memory cells with the 3D array separately by tier, which in turn facilitates connecting, e.g., by an address decoder, to access lines or data lines extending horizontally along the tiers.

In one example, the memory cells are one-transistor, one-capacitor (1T1C) cells, each storing one bit of data in a storage capacitor that can be read from or written to via an associated access transistor. The storage capacitors are connected between the drain terminals of the respective access transistors and electrical ground. The access transistors are connected at their source terminals, in groups of cells extending along a first dimension, to respective data lines. The transistor gates are connected to, and may form portions of, access lines that extend along a second, different dimension, and can be selectively driven to cause the access transistors along the access line to conduct and thereby connect the storage capacitors to the respective data lines. As contemplated herein, the access lines may extend horizontally within the tiers of the material stack. The memory array is configured, in some embodiments, with data lines extending vertically through the material stack in the form of data line pillars. In alternative embodiments, the data line pillars extend horizontally within the tiers of the material stack, but perpendicularly to (or, more generally, along a different dimension than) the access lines. In either case, the connections of the capacitors to ground may be established, e.g., with vertically extending ground pillars (e.g., alternating with the data line pillar in the first case). Other types of memory cells (including, e.g., 2T1C cells) and/or other configurations of the memory array and its associated access lines, data lines, and ground lines are also possible.

The access lines in different tiers of the memory array are separately addressable using an electrical interconnect structure as described herein. With reference again to FIGS. 3 and 30, the memory array is formed in one or more memory device regions 304 of the periodic material stack, and the electrical interconnect structure, with contact pillars each extending and connected to one (and only one) tier within the material stack, is formed in a region 300 adjacent to the memory device region(s) 304 (e.g., as shown, in between two memory device regions 304). The memory device and electrical interconnect regions 304, 300 may be divided into multiple adjacent sections 308, each including multiple rows of memory cells in the memory device region 304 and multiple rows of contact pillars in the electrical interconnect region 300 (where the numbers of rows of memory cells and the number of rows of contact pillars may generally differ). Within each section 308, the contact pillars of the electrical interconnect structure collectively provide connections to each tier within the periodic material stack. Via one of the contact pillars in a given section 308, the access lines formed along the rows of cells within that section 308 are addressable and accessible, as a group, separately from the access lines in all other tiers. Additionally, within a given tier, groups of access lines in different sections 308 are separately addressable and accessible via the respective adjacent array of contact pillars in the same section.

While described with respect to horizontal access lines, the electrical interconnect structure can similarly be used to access horizontal data lines separately by tier, as will be readily appreciated by those of ordinary skill in the art.

The above description and the drawings illustrate some embodiments of the invention to enable those skilled in the art to practice the embodiments of the invention. Other embodiments may incorporate structural, logical, electrical, process, and other changes. Examples merely typify possible variations. Portions and features of some embodiments may be included in, or substituted for, those of others. Many other embodiments will be apparent to those of skill in the art upon studying and understanding the above description.

What is claimed is:

1. A stairless electrical interconnect structure for accessing each of a plurality of consecutive tiers within a vertically periodic material stack, each of the plurality of tiers comprising an electrically conductive layer, the electrical interconnect structure comprising:
a plurality of vertical electrically conductive contact pillars embedded within the periodic material stack, each contact pillar extending to and contacting the electrically conductive layer of one of the plurality of tiers, the contact pillars arranged in an array of rows and columns, wherein:
the contact pillars within each column vary in depth between rows so as to collectively contact a specified number n of consecutive tiers of the plurality of consecutive tiers, and
the contact pillars within each row vary in depth between columns so as to collectively contact every n-th tier of the plurality of consecutive tiers.

2. The electrical interconnect structure of claim 1, wherein the contact pillars within each row vary in depth linearly along the row by the specified number n of tiers between adjacent columns.

3. The electrical interconnect structure of claim 1, wherein the array consists of two sub-arrays each including half of the columns, and wherein the contact pillars within each row vary in depth linearly along the row by twice the specified number n of tiers between adjacent columns with each sub-array and are offset by the specified number n of tiers between the two sub-arrays.

4. The electrical interconnect structure of claim 3, wherein the contact pillars within each row increase in depth linearly toward a center of the array between the two sub-arrays to form a stadium structure.

5. The electrical interconnect structure of claim 1, wherein the specified number of tiers is three.

6. The electrical interconnect structure of claim 1, wherein side walls of the plurality of contact pillars are lined by an insulating material that electrically insulates each contact pillar from the electrically conductive layers of all tiers above the tier to which the respective contact pillar extends.

7. The electrical interconnect structure of claim 1, wherein the electrically conductive layers of the plurality of tiers and the plurality of contact pillars are made of tungsten.

8. The electrical interconnect structure of claim 1, wherein the electrically conductive layers alternate with electrically insulating oxide layers.

9. A process of forming a stairless electrical interconnect structure for accessing each of a plurality of tiers within a periodic material stack, the process comprising:
depositing a hard mask over the periodic material stack;
creating a two-dimensional array of vertical openings extending through the hard mask, the openings arranged along rows and columns of the array;
extending the vertical openings, in multiple first-stage etch cycles, to form contact pillar trenches that vary in depth along the rows by exposing an increasing number of columns between successive first-stage etch cycles and etching the exposed columns down by a specified number of tiers of the material stack during each of the first-stage etch cycles;
extending the contact pillar trenches, in multiple second-stage etch cycles, to depths varying along the columns by exposing an increasing number of rows between successive etch cycles and etching the exposed rows down by one tier of the material stack during each second-stage etch cycle; and
following the multiple second-stage etch cycles:
lining side walls of the contact pillar trenches with an electrical insulator material,
etching the contact pillar trenches through to electrically conductive layers of respective tiers immediately below, and
filling the contact pillar trenches with an electrically conductive material to form contact pillars in contact with the respective electrically conductive layers.

10. The process of claim 9, wherein the second-stage etch cycles are equal in number to the specified number of tiers etched during each of the multiple first-stage etch cycles.

11. The process of claim 9, wherein the second-stage etch cycles are equal in number to half of the specified number of tiers etched during each of the multiple first-stage etch cycles, the process further comprising, in an additional etch cycle, extending the contact pillar trenches in half of the columns down by half of the specified number of tiers.

12. The process of claim 11, wherein in a first one of the multiple first-stage etch cycles, the exposed columns consist of a center pair of columns, and wherein in each subsequent one of the multiple first-stage etch cycles, the exposed columns are augmented by an additional pair of columns adjacent to the respective previously exposed columns on both sides.

13. The process of claim 9, wherein exposing an increasing number of columns between successive first-stage etch cycles comprises patterning an etch mask to expose an initial subset of the columns, and trimming the etch mask between subsequent successive first-stage etch cycles to expose one or more additional columns in each of the subsequent first-stage etch cycles.

14. The process of claim 13, wherein exposing an increasing number of columns between successive first-stage etch cycles further comprises, upon depletion of the etch mask, applying a new etch mask, and repeating the patterning and trimming for the new etch mask with a new exposed initial subset of columns.

15. The process of claim 9, wherein in a first one of the multiple second-stage etch cycles, the exposed rows consist of a center pair of rows, and wherein in each subsequent one of the multiple second-stage etch cycles, the exposed rows are augmented by an additional pair of rows adjacent to the respective previously exposed rows on both sides.

16. The process of claim 9, wherein the specified number of tiers etched through during each of the first etch cycles is six.

17. The process of claim 9, wherein the periodic material stack initially comprises insulating and sacrificial material layers with each tier, the process further comprising, following lining of the contact pillar trenches and prior to punching the contact pillar trenches through to the electrically conductive layers, creating the electrically conductive layers by replacing the sacrificial material layers with an electrically conductive material.

18. A memory device comprising:
a periodic material stack comprising a plurality of tiers, each tier comprising an electrically conductive layer;
a three-dimensional (3D) memory array formed in a first region of the periodic material stack, the memory array comprising tiers of memory cells formed in respective tiers of the periodic material stack and associated horizontal access lines to the cells formed in the electrically conductive layers; and
an electrical interconnect structure formed in a second region of the periodic material stack adjacent to the first region, the electrical interconnect structure comprising a plurality of electrically conductive contact pillars embedded within and vertically extending through the periodic material stack, each contact pillar extending to and contacting the electrically conductive layer of one of the plurality of tiers, the contact pillars arranged in an array of rows and columns, wherein:
the contact pillars within each column vary in depth between rows so as to collectively contact a specified number n of consecutive tiers of the plurality of consecutive tiers, and
the contact pillars within each row vary in depth between columns so as to collectively contact every n-th tier of the plurality of consecutive tiers.

19. The memory device of claim 18, wherein the contact pillars within each row vary in depth linearly along the row by the specified number n of tiers between adjacent columns.

20. The memory device of claim 18, wherein the array consists of two sub-arrays each including half of the columns, and wherein the contact pillars within each row vary in depth linearly along the row by twice the specified number n of tiers between adjacent columns with each sub-array and are offset by the specified number n of tiers between the two sub-arrays.
